(19) United States
(12) Patent Application Publication
(10) Pub. No.: US 2013/0239891 A1
(43) Pub. Date: Sep. 19, 2013

(54) DEPOSITION APPARATUS AND RECOVERY APPARATUS

(71) Applicants: Tohru Sonoda, Osaka (JP); Shinichi Kawato, Osaka (JP); Satoshi Inoue, Osaka (JP); Satoshi Hashimoto, Osaka (JP)

(72) Inventors: Tohru Sonoda, Osaka (JP); Shinichi Kawato, Osaka (JP); Satoshi Inoue, Osaka (JP); Satoshi Hashimoto, Osaka (JP)

(73) Assignee: Sharp Kabushiki Kaisha, Osaka (JP)

(21) Appl. No.: 13/990,785

(22) PCT Filed: Nov. 28, 2011
(86) PCT No.: PCT/JP2011/077433

§ 371 Date: May 30, 2013

(30) Foreign Application Priority Data
Dec. 3, 2010 (JP) 2010-270607

(51) Int. Cl. H01L 31/18

(52) U.S. Cl. CPC H01L 31/18
USPC 118/719; 118/715

(57) ABSTRACT

At least a part of a shield plate (3) and a shutter (4) is constituted by a plurality of small pieces (3a, 3b, 4a, and 4b) linked to one another, and each of the plurality of small pieces (3a, 3b, 4a, and 4b) is provided with a linking section or linking sections by which each of the plurality of small pieces is linkable to one another and delinkable from one another.

### TECHNICAL FIELD

The present invention relates to a vapor deposition device and a recovery device each of which can collect a vapor deposition material deposited on a section which requires no vapor deposition material.

### BACKGROUND ART

Recent years have witnessed practical use of a flat-panel display in various products and fields. This has led to a demand for a flat-panel display that is larger in size, achieves higher image quality, and consumes less power.

Under such circumstances, great attention has been drawn to an organic EL display device that (i) includes an organic electroluminescence (hereinafter abbreviated to “EL”) element which uses EL of an organic material and that (ii) is an all-solid-state flat-panel display which is excellent in, for example, low-voltage driving, high-speed response, self-emitting, and wide viewing angle characteristics.

An organic EL display device includes, for example, (i) a substrate made up of members such as a glass substrate and TFTs (thin film transistors) provided to the glass substrate and (ii) organic EL elements provided on the substrate and electrically connected to the TFTs.

The organic EL element (i) is a light-emitting element which can carry out a high-intensity light-emitting by a low voltage direct current drive and (ii) is configured such that a first electrode, an organic EL layer, and a second electrode are laminated in this order. Further, the first electrode electrically connects to the TFT.

Moreover, as the organic EL layer, an organic layer in which a hole injection layer, a hole transfer layer, an electron blocking layer, a luminescent layer, a hole blocking layer, an electron transfer layer, an electron injection layer, and the like are laminated is provided between the first electrode and the second electrode.

A full-color organic EL display device typically includes, as sub-pixels aligned on a substrate, organic EL elements of red (R), green (G), and blue (B). The full-color organic EL display device carries out an image display by, with use of TFTs, selectively causing the organic EL elements to each emit light with a desired luminance.

In producing such an organic EL display device, a luminescent layer at least made of an organic luminescent material which emits light of the colors is formed of a predetermined pattern for each organic EL element which is a light-emitting element.

As a method for producing such an organic EL layer and a second electrode, for example, a vacuum vapor deposition method using a vapor deposition mask known as a shadow mask, an ink-jet method, and a laser transfer method can be applied.

Among these methods, the vacuum vapor deposition method is the most common method at present. According to the vacuum vapor deposition method, under high vacuum, a vapor deposition material which is put in a container for heating, known as a crucible or a boat, is heated so as to be sublimated, thereby depositing a thin film of the vapor deposition material on a substrate.

At that time, a vapor-deposited film can be formed on a desired region only by (i) causing a shadow mask in which only a desired region is open to be closely contacted with the substrate and (ii) carrying out a vapor deposition via the opening of the shadow mask.

However, according to the vacuum vapor deposition method, except for the vapor-deposited film deposited on the substrate, the material entirely results in a loss, so as not to become a vapor-deposited film provided on the organic EL display device.

In other words, the vapor deposition materials adhered to (i) a shutter which determines whether or not vapor deposition particles are released toward the substrate placed directly above the crucible or the like containing the vapor deposition material, (ii) a shield plate installed in a replaceable state so as to protect an inside of a chamber of a vapor deposition device from being contaminated with the vapor deposition material, and (iii) a non-opening section and the like of the shadow mask result in waste.

In general, a material constituting the second electrode is metal, and a material unit price of the metal is less expensive, as compare with that of an organic material constituting the organic EL layer. Meanwhile, the organic material constituting the organic EL layer is a special functional material having electroconductivity, a carrier transit property, a light-emitting property, thermal and electrical stability, and the like, so that the material unit price of the organic material is highly expensive.

Nevertheless, as described above, except for the organic material deposited on the substrate, the material entirely results in a loss. Accordingly, a large amount of vapor deposition material is used per substrate for which a vapor deposition process is carried out, so that the vapor deposition process becomes costly. As a result, a cost price of the organic EL display device increases.

As a method for solving the problem described above, it is possible to employ a method for collecting and reusing a material adhered to a section other than the substrate.

Patent Literature 1 discloses a method for capturing, in a storage section, a vapor deposition material adhered to a shutter by carrying out a reheating and a cooling in a shroud.

Further, Patent Literature 2 discloses a method for heating a vapor deposition material adhered to a shutter plate by a heater in a shutter, so as to melt and then drop the vapor deposition material into a vapor deposition source.

It is described that these methods make it possible to collect and reuse the vapor deposition material adhered to the shutter.

FIG. 16 is a view illustrating a schematic structure of a vacuum vapor deposition device 200 described in Patent Literature 3.

As illustrated in FIG. 16, the vacuum vapor deposition device 200 includes a vapor deposition chamber 211 whose inside is vacuum, and a shield plate 216 is provided along an interior wall of the vapor deposition chamber 211.

A substrate holder 219 holding a processed substrate 220 and a vapor deposition masking member 230 is provided at a position in an upper portion in the vapor deposition chamber 211, and the vapor deposition masking member 230 is placed on a predetermined position on a surface of the processed substrate 220 on which surface a film is to be formed.

A plurality of mask openings 310 corresponding to a vapor deposition pattern of the processed substrate 220 are formed on the vapor deposition masking member 230.

Moreover, a shutter section 215 which can, if necessary, shut off an upper section of a vapor flow releasing hole 270 is provided.

As illustrated in FIG. 16, the vacuum vapor deposition device 200 of Patent Literature 3 is configured such that a vapor deposition material recovery tool 217 having a blocking wall 271 and a vapor flow releasing hole 270 is provided so as to cover a vapor outlet 212a. Patent Literature 3 discloses a method for collecting and reusing a vapor deposition material deposited on the blocking wall 271 by (i) performing a vapor deposition in a state in which a divergence angle V1 of a vapor flow traveling from a vapor deposition source 212 to the processed substrate 220 is controlled and then (ii) taking out the vapor deposition material recovery tool 217 so as to collect the vapor deposition material deposited on the blocking wall 271 in order to reuse the vapor deposition material.

Patent Literature 3 describes that the configuration above makes it possible to reduce an amount of a vapor deposition material wastefully deposited on a section other than the processed substrate 220, in other words, the configuration above makes it possible to efficiently collect and reuse the vapor deposition material by causing the conventionally-wastefully deposited portion of the vapor deposition material to be adhered to the blocking wall 271 of the vapor deposition material recovery tool 217.

### CITATION LIST

### Patent Literature

Patent Literature 1
Japanese Patent Application Publication, Tokukaihei, No. 10-168559 A (Publication Date: Jun. 23, 1998)

Patent Literature 2
Japanese Patent Application Publication, Tokukai, No. 2008-127642 A (Publication Date: Jun. 5, 2008)

Patent Literature 3
Japanese Patent Application Publication, Tokukai, No. 2008-223102 A (Publication Date: Sep. 25, 2008)

### SUMMARY OF INVENTION

### Technical Problem

According to the methods described in Patent Literatures 1 and 2, it is possible to collect and reuse the vapor deposition material adhered to the shutter. However, the vapor deposition material adhered to a section other than the shutter in the chamber cannot be collected.

In a mass production process, a vapor deposition process is continuously carried out for a large number of substrates after a vapor deposition speed is stabilized. Accordingly, the vapor deposition process is carried out almost always in the mass production, except for a little time period in which (i) the substrates are moved into or out of the chamber or (ii) shadow masks are positionally adjusted to be closely contacted with the substrates. In other words, the shutter is open in most of processing time of the mass production.

Therefore, in an actual mass production process, a large amount of vapor deposition material is adhered to the section other than the shutter. For this reason, the vapor deposition material cannot be efficiently collected and reused by collecting only the vapor deposition material adhered to the shutter.

Further, in Patent Literature 2, a process of thoroughly dropping the dissolved material into the vapor deposition source is required (the dropping is a gravity-dependent dropping so that acceleration is impossible). Therefore, if an enough time period for carrying out such a process is provided, a throughput of the device will decrease.

Moreover, in a case where the shutter, the shroud, and the storage section (in Patent Literature 1) and the shutter (in Patent Literature 2) are produced for each vapor deposition source, each of such members should be designed individually to have a shape and a size suitable for those of the vapor deposition source, accordingly.

Therefore, versatility of such members decreases, and as a result, a device cost increases. Further, the device cost increases by use of a component such as a shutter and a storage section which have a heating function.

Furthermore, the method described in Patent Literature 2 can be applied only to a material which is dissoluble.

Moreover, according to the method described in Patent Literature 3, it becomes impossible to collect a material adhered to a section other than the blocking wall and the processed substrate in a case where an amount of such a material is low.

As described above, according to the configuration described in Patent Literature 3, as in Patent Literatures 1 and 2, the device cost increases due to (i) necessity of individually designing the vapor deposition material recovery tool in accordance with each of the vapor deposition sources and (ii) an introduction of a new component, that is, the vapor deposition material recovery tool.

As described above, according to the conventional methods, it is impossible to efficiently collect a vapor deposition material at a low cost.

The present invention is accomplished in view of the foregoing problem described above, and it is an object of the present invention to provide a vapor deposition device and a recovery device each of which can efficiently collect a vapor deposition material at a low cost.

### Solution to Problem

In order to attain the object, a vapor deposition device of the present invention is a vapor deposition device for depositing vapor deposition particles onto a substrate in a vapor deposition chamber, the vapor deposition particles being released from a vapor deposition material containing section provided in a vapor deposition source, wherein: vapor deposition particles released in a first direction from the vapor deposition material containing section is deposited on the substrate, vapor deposition particles released in a second direction different from the first direction is deposited on a first member which is removable from the vapor deposition device, at least a part of the first member is constituted by a plurality of small pieces linked to one another, and each of the plurality of small pieces is provided with a linking section or linking sections by which each of the plurality of small pieces is linkable to one another and delinkable from one another.

According to the configuration above, (i) vapor deposition particles deposited on a section other than the substrate are deposited on the first member which is removable from the vapor deposition device, (ii) at least a part of the first member is constituted by a plurality of small pieces linked to one another, and (iii) each of the plurality of small pieces is provided with a linking section or linking sections by which each of the plurality of small pieces are linkable to one another and delinkable from one another.

Therefore, the first member (i) is not required to be individually designed and produced in accordance with a size and a shape of a vapor deposition chamber and a vapor deposition source of each of the vapor deposition devices and (ii) can be produced, by linking (assembling) general-purpose small pieces, for a vapor deposition chamber and a vapor deposition source of a variety of vapor deposition devices.

Moreover, the first member is removable from the vapor deposition device, and each of the plurality of small pieces constituting the first member is easily delinkable from one another.

This makes it possible to produce a vapor deposition device which can efficiently collect a vapor deposition material at a low cost.

Note that the first direction refers to a direction which is not shut off by the first member, among directions in which the vapor deposition particles released from the vapor deposition material containing section travel toward the substrate. Further, the second direction refers to all directions other than the first direction.

In order to attain the object, a recovery device of the present invention includes a storage member in which the plurality of small pieces having been provided in the vapor deposition device are stored; a sublimation section for heating at least either the plurality of small pieces or the storage member so as to sublimate vapor deposition particles deposited on the plurality of small pieces; and a first capturing section for capturing the vapor deposition particles thus sublimated.

According to the configuration above, the sublimation section and the first capturing section are provided. Accordingly, it is possible to separate a step of sublimating vapor deposition particles in the sublimation section and a step of capturing, in the first capturing section, the vapor deposition particles thus sublimated, so as to improve a throughput of the recovery device.

In order to attain the object, a recovery device of the present invention includes the vapor deposition device; a storage member for storing therein the plurality of small pieces on which vapor deposition particles are deposited in the vapor deposition chamber provided in the vapor deposition device; a sublimation section for heating at least either the plurality of small pieces or the storage member so as to sublimate the vapor deposition particles deposited on the plurality of small pieces; and a first capturing section for capturing the vapor deposition particles thus sublimated.

According to the configuration above, the vapor deposition device is provided in the recovery device, so that it is possible to efficiently collect a vapor deposition material at a low cost by use of the plurality of small pieces on which a vapor deposition material obtained in the recovery device is deposited.

### Advantageous Effects of Invention

As described above, a vapor deposition device of the present invention is a vapor deposition device wherein: vapor deposition particles released in a first direction from the vapor deposition material containing section is deposited on the substrate, vapor deposition particles released in a second direction different from the first direction is deposited on a first member which is removable from the vapor deposition device, at least a part of the first member is constituted by a plurality of small pieces linked to one another, and each of the plurality of small pieces is provided with a linking section or linking sections by which each of the plurality of small pieces is linkable to one another and delinkable from one another.

Further, as described above, a recovery device of the present invention includes a storage member in which the plurality of small pieces having been provided in the vapor deposition device are stored; a sublimation section for heating at least either the plurality of small pieces or the storage member so as to sublimate vapor deposition particles deposited on the plurality of small pieces; and a first capturing section for capturing the vapor deposition particles thus sublimated.

Moreover, as described above, a recovery device of the present invention includes the vapor deposition device; a storage member for storing therein the plurality of small pieces on which vapor deposition particles are deposited in the vapor deposition chamber provided in the vapor deposition device; a sublimation section for heating at least either the plurality of small pieces or the storage member so as to sublimate the vapor deposition particles deposited on the plurality of small pieces; and a first capturing section for capturing the vapor deposition particles thus sublimated.

Therefore, it is possible to produce a vapor deposition device and a recovery device each of which can efficiently collect a vapor deposition material at a low cost.

### BRIEF DESCRIPTION OF DRAWINGS

FIG. 1 is a view illustrating a schematic structure of a vacuum vapor deposition device of an embodiment of the present invention.

FIG. 2 is a view illustrating a shape and an assembling method of a plurality of small pieces used in a vacuum vapor deposition device of an embodiment of the present invention.

FIG. 3 is a view illustrating another example of a plurality of small pieces which can be used in a vacuum vapor deposition device of an embodiment of the present invention.

FIG. 4 is a view illustrating further another example of a plurality of small pieces which can be used in a vacuum vapor deposition device of an embodiment of the present invention.

FIG. 5 is a view illustrating a plurality of small pieces which are delinked from one another and are arranged and stored in a stocker.

FIG. 6 is a view illustrating a schematic structure of a recovery device of an embodiment of the present invention, for collecting a vapor deposition material adhered to the plurality of small pieces illustrated in FIG. 2.

FIG. 7 is a view illustrating a schematic structure of a recovery device of a modification of an embodiment of the present invention.

FIG. 8 is a view illustrating a schematic structure of a recovery device of another embodiment of the present invention.

FIG. 9 is a view illustrating a schematic structure of a vacuum vapor deposition device of further another embodiment of the present invention.

FIG. 10 is a view illustrating a schematic structure of a recovery device of further another embodiment of the present invention.

FIG. 11 is a view illustrating a schematic structure of a vacuum vapor deposition device of further another embodiment of the present invention, which vacuum vapor deposition device includes a vapor deposition source which can store a stocker.

FIG. 12 is a view illustrating a schematic structure of a vacuum vapor deposition device of further another embodiment of the present invention, in which vacuum vapor deposition device a control plate is constituted by a plurality of small pieces.

FIG. 13 is a cross-sectional view illustrating an organic EL element constituting a display section of a conventional organic EL display device.

FIG. 14 is a schematic view illustrating a method for forming a pattern vapor-deposited film on a substrate by a vacuum vapor deposition method.

FIG. 15 is a view showing a process of producing an organic EL display device.

FIG. 16 is a view illustrating a schematic structure of a vacuum vapor deposition device described in Patent Literature 3.

### DESCRIPTION OF EMBODIMENTS

Embodiments of the present invention will be described below in detail with reference to the drawings. Note, however, that the dimensions, materials, shapes, relative locations, and the like of respective constituent elements described in Embodiments are illustrative only, and that the scope of the present invention should not be narrowly construed based on them.

### Embodiment 1

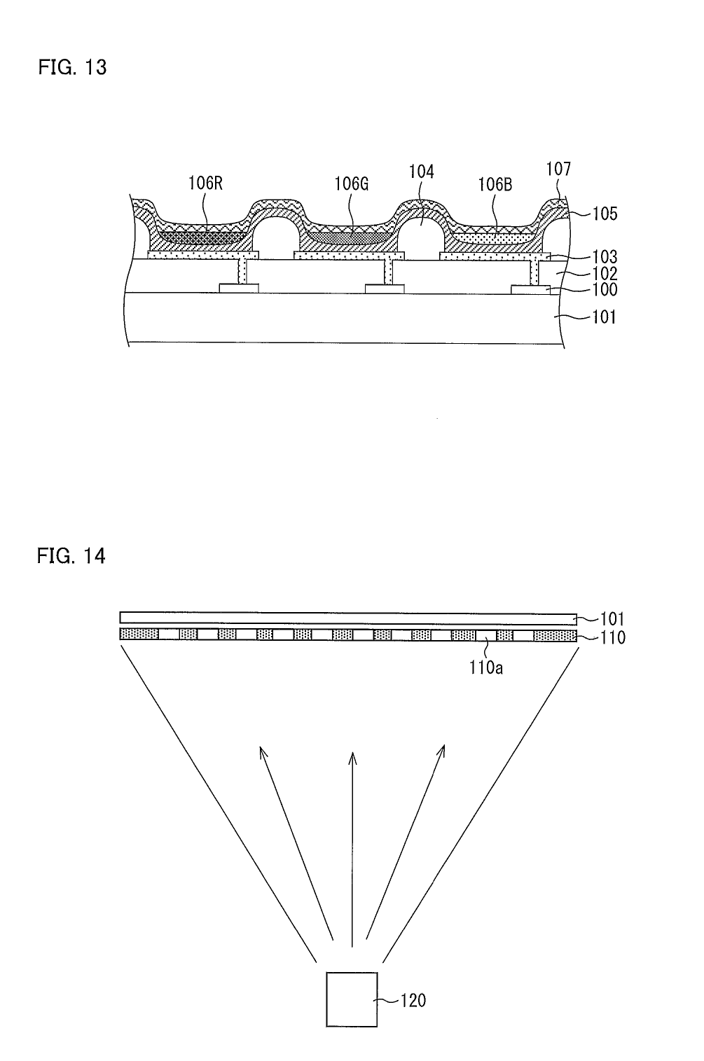

FIG. 13 is a cross-sectional view of organic EL elements that constitute a display section of an organic EL display device.

There are provided, on a substrate 101 where thin film transistors (TFTs) 100 are provided, an interlayer insulating film 102, first electrodes 103, and edge covers 104.

For example, alkali-free glass or plastic can be employed as the substrate 101. Embodiment 1 employs, as the substrate 101, an alkali-free glass substrate having a thickness of 0.7 mm.

A known photosensitive resin can be employed as each of the interlayer insulating film 102 and the edge covers 104. Examples of such a known photosensitive resin encompass an acrylic resin and a polyimide resin.

In Embodiment 1, a photosensitive acrylic resin is employed as each of the interlayer insulating film 102 and the edge covers 104.

The first electrodes 103 are formed by (i) depositing an electrode material by a method such as sputtering and (ii) then patterning the electrode material in shapes for respective pixels by photolithography and etching.

The first electrodes 103 can be made of any of various electrically conductive materials. Note, however, that the first electrodes 103 need to be transparent or semi-transparent in a case where the organic EL display device is a bottom emission organic EL element in which light is emitted towards a substrate side. Meanwhile, a second electrode 107 needs to be transparent or semi-transparent in a case where the organic EL display device is a top emission organic EL element in which light is emitted from a side opposite to the substrate side.

The TFTs are prepared by a known method. Embodiment 1 will discuss how to produce an active matrix organic EL display device in which the TFTs are provided for respective pixels. Note, however, that Embodiment 1 is not limited to this. Embodiment 1 is applicable also to a passive matrix organic EL display device in which no TFT is provided.

The edge covers 104 cover edge parts of the first electrodes 103 so as to prevent the corresponding first electrodes 103 and the second electrode 107 from short-circuiting due to a reduction in thickness of an organic EL layer in the edge parts of the corresponding first electrodes 103. Each first electrode 103 is exposed in a corresponding area between adjacent edge covers 104. Note that such a corresponding area serves as a light-emitting section of a corresponding pixel.

Each organic EL layer is formed on a corresponding first electrode 103. The organic EL layer is made up of, for example, a hole injection layer/hole transfer layer 105, luminescent layers (106R, 106G, and 106B), and an electron transfer layer/an electron injection layer (not illustrated). The electron transfer layer/electron injection layer is formed in shapes identical to the second electrode 107.

The organic EL layer can, as needed, further include a carrier blocking layer (not illustrated) for blocking a flow of carriers such as holes and electrons. A single layer can have a plurality of functions. For example, one layer which serves as both a hole injection layer and a hole transfer layer can be formed.

In Embodiment 1, (a) the first electrode 103, serving as an anode, (b) the hole injection layer/hole transfer layer 105, (c) the luminescent layers (106R, 106G, and 106B), (d) the electron transfer layer (not illustrated), (e) the electron injection layer (not illustrated), and (f) the second electrode 107 serving as a cathode, are stacked in this order from a first electrode 103 side.

Note that, in a case where the first electrode 103 is intended to serve as a cathode, the order in which the layers are stacked is reversed.

Since Embodiment 1 employs a bottom emission organic EL element, ITO (indium tin oxide) is employed as the first electrode 103. The organic EL layer can be made of a known material.

Further, it is possible to use, as a material for the luminescent layer (106R, 106G, 106B), a single material or a mixed material in which a material (i.e., guest material or dopant) is mixed in another material (i.e., host material). In Embodiment 1, the luminescent layer (106R, 106G, 106B) is formed of the single material.

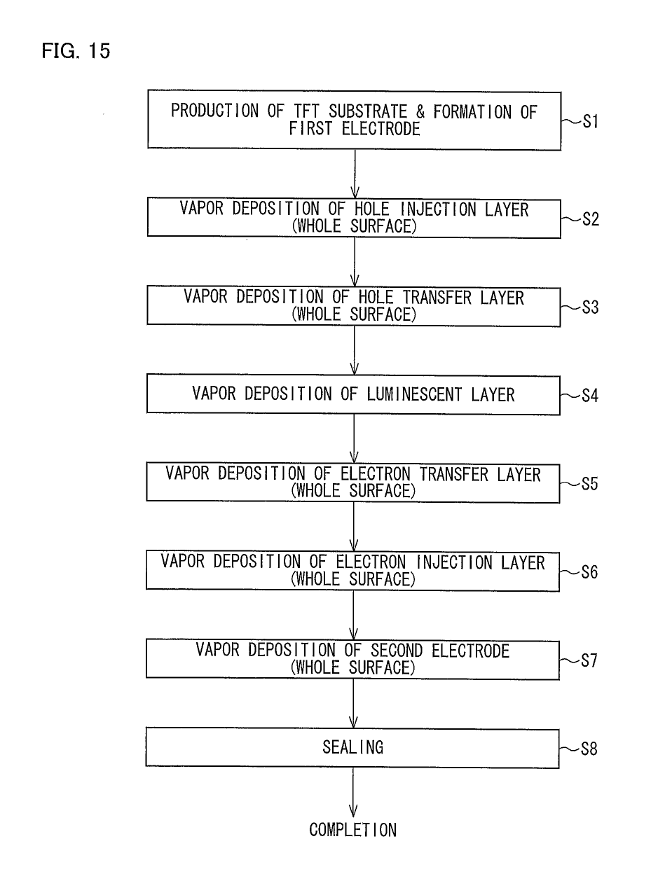

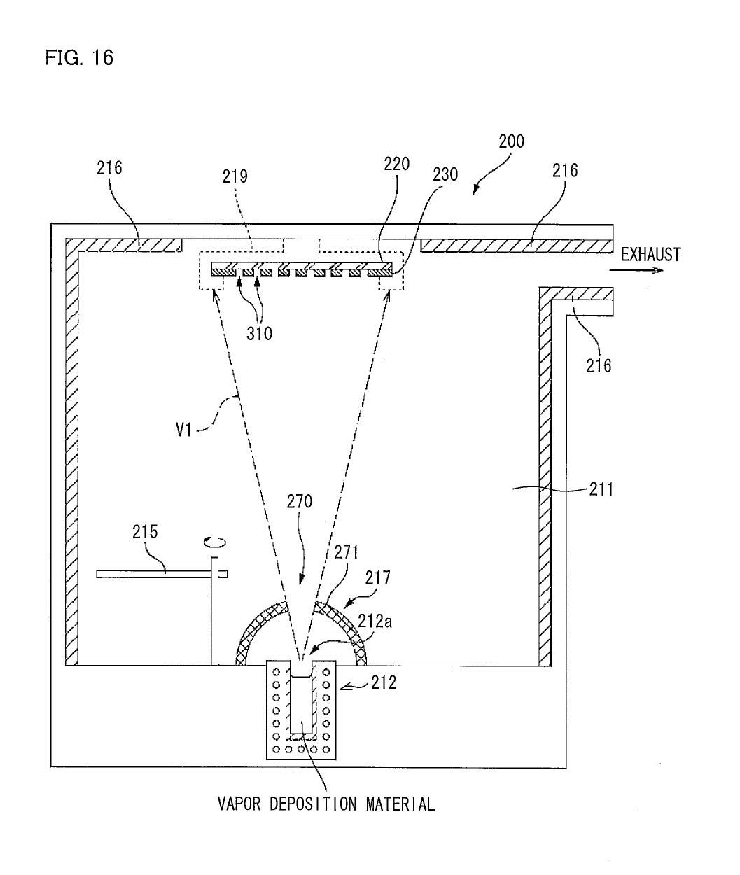

The following description discusses, with reference to FIGS. 14 and 15, a method for forming an organic EL layer on the substrate 101 on which members including the first electrode 103 illustrated in FIG. 13 are formed.

FIG. 14 is a schematic view illustrating a method for forming a pattern vapor-deposited film on a substrate by the vacuum vapor deposition method.

As illustrated in FIG. 14, a vapor deposition material is heated so as to be sublimated in the vapor deposition source 120. Via a shadow mask 110 having an opening 110a in a desired position, the vapor deposition particles thus sublimated reaches the substrate 101 on which the members including the first electrode 103 illustrated in FIG. 13 are formed.

The shadow mask 110 is closely contacted with the substrate 101. This causes to form a vapor-deposited film in a desired position on the substrate 101.

As to the hole injection layer/hole transfer layer 105, the electron transfer layer, the electron injection layer, and the second electrode 107, each of which is illustrated in FIG. 13, these layers are formed over a whole surface of the display section. Thus, the shadow mask 110 for forming such a layer is an open mask extended over the whole surface of the display section and opened only where the layer should be formed.

Meanwhile, in FIG. 14, in a case where a film forming of the luminescent layer (106R, 106G, 106B) is performed, such a film forming is performed by use of, as the shadow mask 110, a fine mask in which only the above-mentioned region is open.

FIG. 15 is a view showing a process of producing an organic EL display device.

First, the substrate 101 on which the first electrode 103 is formed on a TFT substrate is produced (S1).

Then, the hole injection layer/hole transfer layer 105 is formed on a whole surface of the substrate 101 by the vacuum vapor deposition method (S2, S3).

Next, the luminescent layer (106R, 106G, 106B) is formed on a given position, by use of the fine mask as the shadow mask 110, by the vacuum vapor deposition method (S4).

Then, the electron transfer layer, the electron injection layer, and the second electrode 107 are formed in this order by the vacuum vapor deposition method (S5, S6, S7).

As described above, with respect to the substrate in which the vapor deposition is completed, sealing is carried out in a region (display section) in which the organic EL element is formed. (S8) The sealing protects the organic EL element from being deteriorated by moisture or oxygen in the air.

The sealing can be carried out by a method for forming, by a CVD method, a film which does not easily transmit moisture or oxygen in the air, a method for assembling glass substrates or the like by an adhesive, or the like.

According to the steps described above, the organic EL element device is produced, and this enables a desired display by applying a current from a driving circuit formed outside to an organic EL element in each of pixels, so as to emit light.

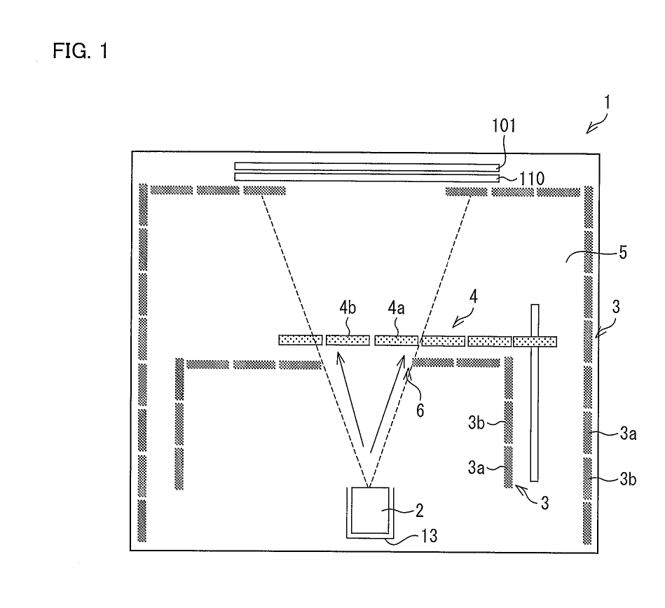

The following description discusses, with reference to FIG. 1, a vacuum vapor deposition device 1 which can be used in forming an organic EL layer on the substrate 101 in which the first electrode 103 is formed on the TFT substrate in the process shown in FIG. 15 of producing the organic EL display device.

FIG. 1 is a view illustrating a schematic structure of the vacuum vapor deposition device 1.

In a vacuum chamber 5, a vapor deposition material containing section 2 provided in a vapor deposition source 13, a shield plate 3, and a shutter 4 are provided.

Only one vapor deposition material containing section 2 is provided in the vacuum chamber 5, and the shield plate 3 protects another component in the chamber 5 from being contaminated with an adherence of vapor deposition particles.

Moreover, the shutter 4 prevents the vapor deposition particles from being released (injected) in the vacuum chamber 5 in a case where a vapor deposition is not required (e.g., a time period until a stable vapor deposition speed is obtained, a time period in which the substrate 101 does not exist, or a time period before positioning of the substrate 101 and the shadow mask 110 is completed to placed the shadow mask 110 on the substrate 101). In other words, the shutter 4 functions to open or to shut off a releasing hole 6 of the shield plate 3.

Each of the shield plate 3 and the shutter 4 is constituted by assembling a plurality of small pieces 3a, 3b, 4a, and 4b, each of which is in a substantially quadrangular shape.

As to a size of each of the plurality of small pieces 3a, 3b, 4a, and 4b, one side is substantially 10 cm and the other sides are 5 cm to 10 cm, and a plate thickness is substantially 1 mm herein.

The plurality of small pieces 3a, 3b, 4a, and 4b are assembled so as to form a desired overall shape. Further, the plurality of small pieces 3a, 3b, 4a, and 4b are assembled so that no space is formed between the plurality of small pieces 3a, 3b, 4a, and 4b in order to prevent the vapor deposition particles from going through the space between the plurality of small pieces 3a, 3b, 4a, and 4b, so as to contaminate another component in the vacuum chamber 5.

In Embodiment 1, stainless steel (SUS) is used as a material of the plurality of small pieces 3a, 3b, 4a, and 4b.

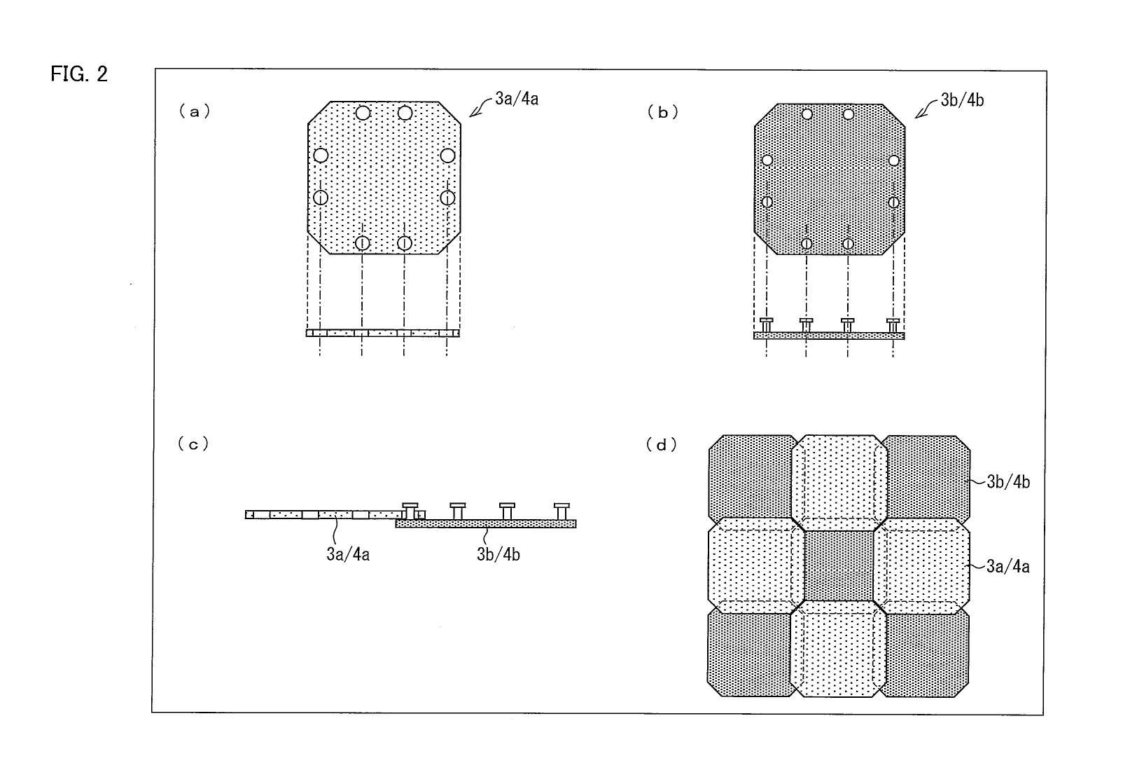

Moreover, in Embodiment 1, the plurality of small pieces 3a, 3b, 4a, and 4b are constituted so as to be in the shape illustrated in FIG. 2. However, the shape of the plurality of small pieces 3a, 3b, 4a, and 4b is not limited to this. The plurality of small pieces 3a, 3b, 4a, and 4b may be in any shape and size, provided that the plurality of small pieces 3a, 3b, 4a, and 4b can be easily assembled and stored in a stocker described later. Further, some of the sides of each of the plurality of small pieces 3a, 3b, 4a, and 4b may be curved.

FIG. 2 is a view illustrating a method used in Embodiment 1. Each of the plurality of small pieces 3a, 3b, 4a, and 4b is in a substantially quadrangular shape, but a corner section of the quadrangular is beveled, so that each of the plurality of small pieces 3a, 3b, 4a, and 4b forms an octagon shape.

The plurality of small pieces 3a, 3b, 4a, and 4b are assembled by engaging, as illustrated in (c) of FIG. 2, a female member having a hole (linking section) illustrated in (a) of FIG. 2 with a male member having a projecting section (linking section) illustrated in (b) of FIG. 2.

For example, the shield plate 3 and the shutter 4 as a component having a wall-like shape in the chamber 5 can be assembled by arranging the female member and the male member in two dimensions as illustrated in (d) of FIG. 2.

In this case, even in a case where the plurality of small pieces 3a, 3b, 4a, and 4b are arranged in two dimensions, since the corner section of each of the plurality of small pieces 3a, 3b, 4a, and 4b is beveled, the component can be assembled such that each of members of the component does not interfere each other.

Furthermore, the engagement of the hole of the female section and the projecting section of the male section with each other (i) prevents the plurality of small pieces from being delinked from one another by themselves and (ii) prevents the component from being disassembled into small pieces.

It is possible to produce a component having a wall-like shape in any size by repeating, a plurality of times, the process illustrated in (d) of FIG. 2.

Note that Embodiment 1 discusses, as an example, the vacuum vapor deposition device 1 including the shutter 4 together with the shield plate 3. However, the present invention is also applicable to a configuration without the shutter 4.

Further, in Embodiment 1, an entire section of each of the shield plate 3 and the shutter 4 is constituted by the plurality of small pieces 3a, 3b, 4a, and 4b. However, it is also possible that only a part of the entire section is constituted by the plurality of small pieces 3a, 3b, 4a, and 4b.

As described above, each of the plurality of small pieces 3a, 3b, 4a, and 4b includes the linking section by which each of the plurality of small pieces is linkable to one another and delinkable from one another.

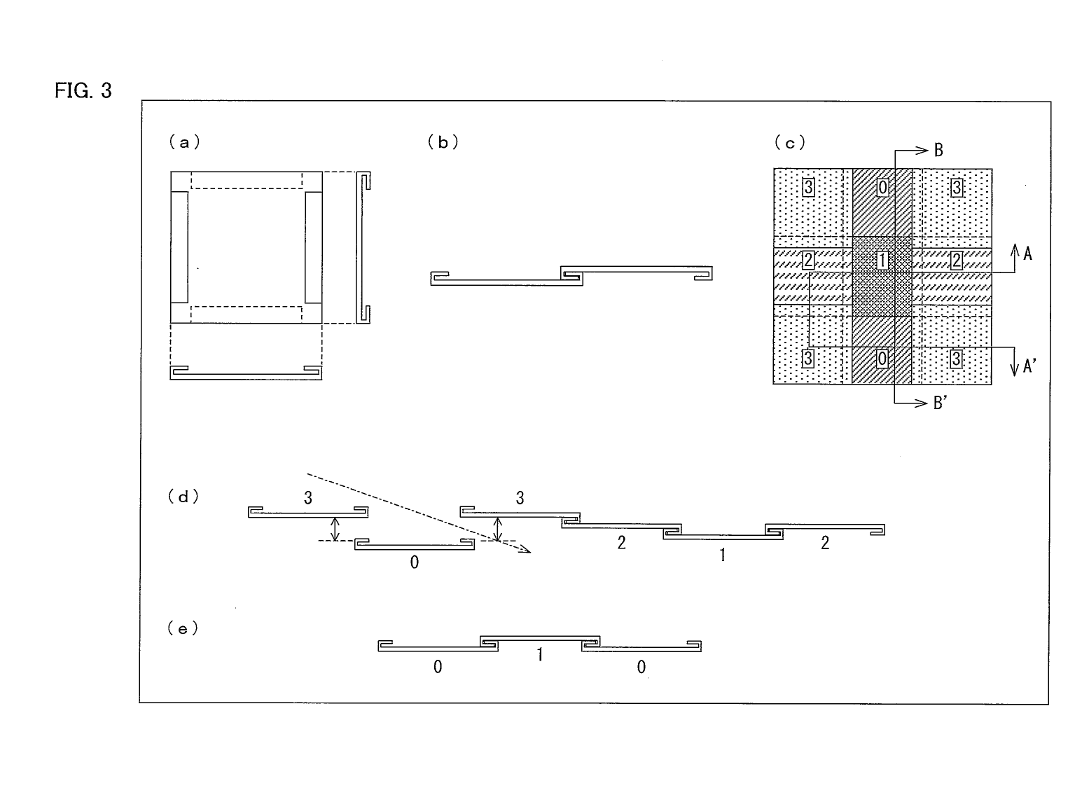

FIG. 3 is a view illustrating another example of a plurality of small pieces which can be employed in Embodiment 1.

As illustrated in FIG. 3, each of the plurality of small pieces is in a quadrangular shape whose four sides have turned edge sections.

As to the turned edge sections, as illustrated in (a) of FIG. 3, the turned edge sections of two of the four sides facing each other are turned in one way and the turned edge sections of another two of the four sides are turned in an opposite way.

The plurality of small pieces are assembled by engaging the turned edge sections with each other as illustrated in (b) of FIG. 3.

For example, the component having a wall-like shape in the chamber 5 can be assembled by arranging each of the plurality of the small pieces in two dimensions as illustrated in (c) of FIG. 3.

Note that the number illustrated on each of the plurality of small pieces indicates a layer number in (c) of FIG. 3. The lowest layer is labeled as a zero layer, and the layers with greater layer numbers are located nearer to a viewer of (c) of FIG. 3.

The component can be assembled such that each of the plurality of small pieces does not interfere one another by laminating the plurality of small pieces as illustrated in (c) of FIG. 3.

Furthermore, the engagement of the turned edge sections with each other (i) prevents the plurality of small pieces from being delinked from one another by themselves and (ii) prevents the component from being disassembled into small pieces.

(d) of FIG. 3 illustrates a cross section along the line A-A′, and (e) of FIG. 3 illustrates a cross section along the line B-B′.

Each number illustrated in (d) and (e) of FIG. 3 is the layer number described above. In a case where the plurality of small pieces are assembled as illustrated in (c) of FIG. 3, as illustrated in (d) of FIG. 3, there is a space between a third layer and the zero layer. Note that such space causes no problem in a case where the plurality of small pieces are positioned such that no vapor deposition flow of a vapor deposition material released from the vapor deposition material containing section goes through such a space.

In other words, the vapor deposition material does not go through the space and is captured by the component assembled with the plurality of small pieces by arranging, as illustrated by the arrow in dashed line in (d) of FIG. 3, a position of the space and the vapor deposition source such that no vapor deposition particles which can go through the space flies.

Moreover, the space is adjustable in accordance with a plate thickness of the plurality of small pieces and a length of the turned edge sections. For example, incidence angles of the vapor deposition particles into the space can be limited by (i) reducing a width of the space by reducing the plate thickness of the plurality of small pieces and (ii) increasing the length of the turned edge sections (increasing a length of a range in which the turned edge sections engaged with each other).

It is possible to produce a component having a wall-like shape in any size by repeating, a plurality of times, the process illustrated in (c) of FIG. 3.

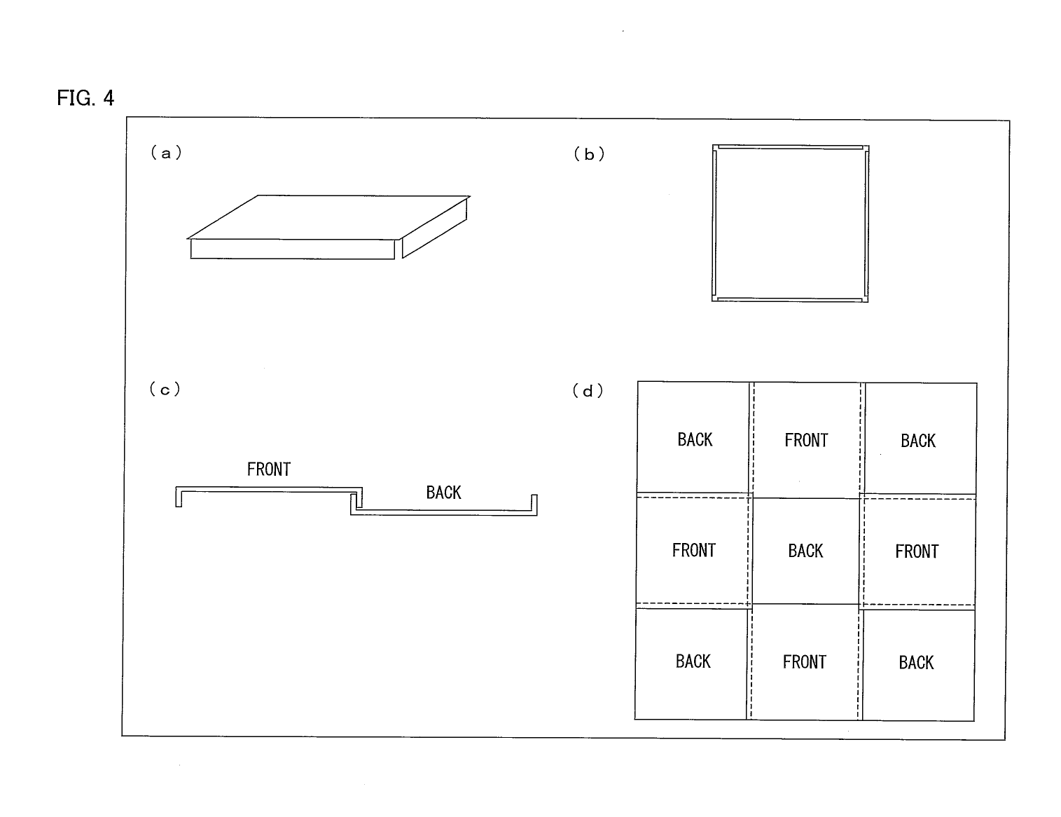

FIG. 4 is a view illustrating further another example of the plurality of small pieces which can be employed in Embodiment 1.

As illustrated in FIG. 4, each of the plurality of small pieces is in a quadrangular shape and four sides of the quadrangular are folded in an L-shape. Note that, as illustrated in (a) of FIG. 4 and (b) of FIG. 4, each of corner sections of the plurality of small pieces does not have such an L-shaped section.

The plurality of small pieces are assembled by engaging the plurality of small pieces with one another in such a manner that front and back surfaces of the small pieces are arranged alternatively as illustrated in (c) of FIG. 4.

For example, the component having a wall-like shape in the chamber 5 can be assembled by arranging each of the plurality of small pieces in two dimensions as illustrated in (d) of FIG. 4.

The corner sections of the plurality of small pieces do not have the L-shaped section. This makes it possible to assemble the component without causing interferences between the plurality of small pieces. Further, each of the plurality of small pieces are overlapped each other at (i) sections in which the plurality of small pieces are engaged with each other and (ii) the corner sections of the plurality of small pieces. This eliminates the space through which the vapor deposition particles can go.

Furthermore, the engagement of the L-shaped sections with each other (i) prevents the plurality of small pieces from being delinked from one another by themselves and (ii) prevents the component from being disassembled into small pieces.

In a case where there is a possibility that only the L-shaped sections are not sufficient to prevent the plurality of small pieces from being delinked from one another, such a case can be dealt with by adding a projection or a hook-shaped structure to the L-shaped sections as appropriate. It is possible to produce a component having a wall-like shape in any size by repeating, a plurality of times, the process illustrated in (d) of FIG. 4.

Moreover, nevertheless to say, assembling of the plurality of small pieces by a screw and a nut is also possible as a method which can be employed in Embodiment 1, for assembling the plurality of small pieces. In this case, however, it is preferable to employ a simple assembling method discussed with reference to FIGS. 2 through 4 because the screw and the nut are contaminated with the vapor deposition material and assembling and disassembling of the component are time-consuming processes.

Furthermore, SUS is employed as a material of the plurality of small pieces 3a, 3b, 4a, and 4b in Embodiment 1. It goes without saying that the present invention is not limited to this, and any material can be selected within a range in which the present invention is applicable.

In Embodiment 1, the vacuum vapor deposition device is prepared for each of the steps shown in FIG. 15 of producing an organic EL display device, and the shield plate 3 and the shutter 4 in which the plurality of small pieces 3a, 3b, 4a, and 4b are employed are applied to only the vacuum vapor deposition device 1 forming the hole injection layer/hole transfer layer.

In a chamber other than that of the vacuum vapor deposition device 1, a shield plate and a shutter which are designed for an individual chamber as in the conventional methods are employed.

Nevertheless to say, the shield plate 3 and the shutter 4 formed with the plurality of small pieces 3a, 3b, 4a, and 4b are also applicable to the other vacuum chamber of the vacuum vapor deposition device 1 than the vacuum chamber for forming the hole injection layer/hole transfer layer.

When the organic EL display device was produced by carrying out the process shown in FIG. 15, the vapor deposition material was deposited on the shield plate 3 and the shutter 4 in the vacuum chamber 5 forming the hole injection layer/hole transfer layer.

The vacuum chamber 5 forming the hole injection layer/hole transfer layer was opened to the air. Then, the shield plate 3 and the shutter 4 to which the vapor deposition material was adhered were delinked from one another into the plurality of small pieces 3a, 3b, 4a, and 4b, and then the plurality of small pieces 3a, 3b, 4a, and 4b were taken out.

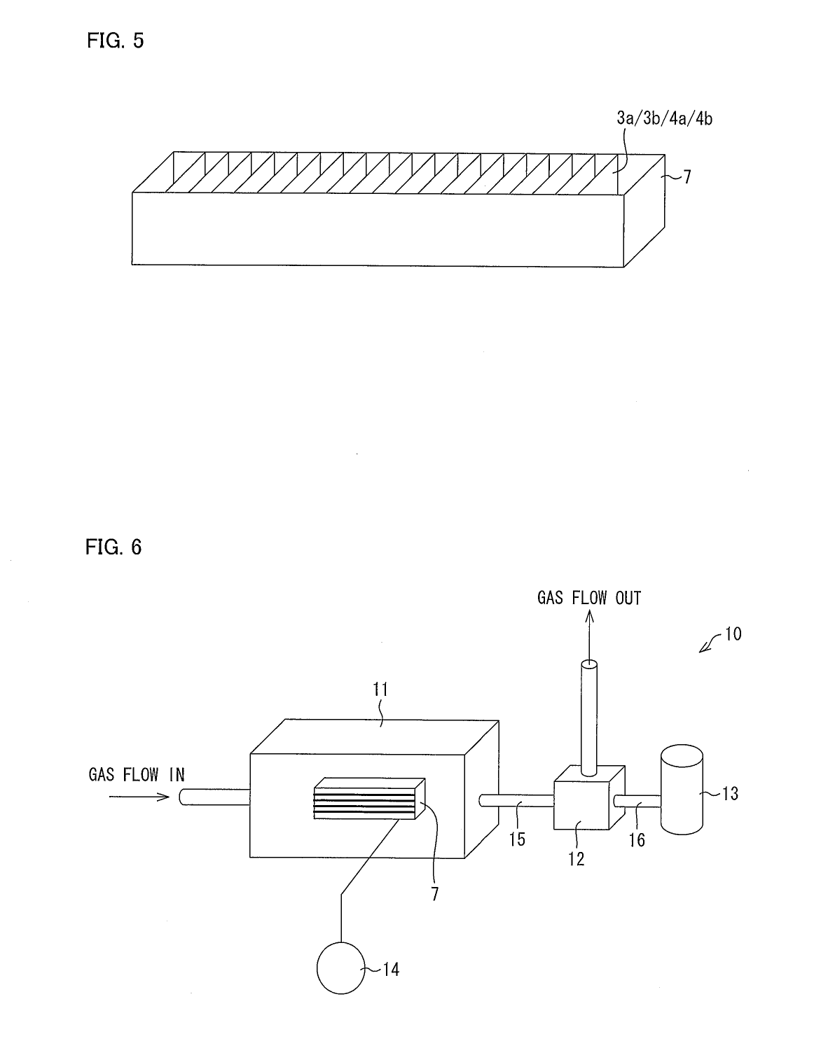

FIG. 5 is a view illustrating the plurality of small pieces 3a, 3b, 4a, and 4b which are delinked from one another and are arranged and stored in a stocker 7.

As illustrated in FIG. 5, the stocker 7 is in a box shape and is configured such that the plurality of small pieces 3a, 3b, 4a, and 4b thus delinked can be inserted so as to be fixedly held.

In Embodiment 1, as the stocker 7, a member (i) whose inside dimension is 10 cm high, 10.5 cm wide, and 50 cm long and (ii) which has a groove in which each of the plurality of small pieces can be arranged in a length direction at intervals of 3 mm is employed. However, the present invention is not limited to this.

FIG. 6 is a view illustrating a schematic structure of a recovery device 10 for collecting a vapor deposition material adhered to the plurality of small pieces 3a, 3b, 4a, and 4b.

As illustrated in FIG. 6, the recovery device 10 is constituted by a resublimation chamber (sublimation section) 11, a storage chamber 12, and a vapor deposition source 13 provided in the vacuum vapor deposition device 1 illustrated in FIG. 1. The resublimation chamber 11 and the storage chamber 12 are connected with each other via a piping 15 which can be opened and closed, and the storage chamber 12 and the vapor deposition source 13 are connected to each other via a piping 16 which can be opened and closed.

In other words, the recovery device 10 is integrally formed with the vacuum vapor deposition device 1, even though only the vapor deposition source 13 of the vacuum vapor deposition device 1 illustrated in FIG. 1 is illustrated in FIG. 6.

Then, the stocker 7 in which the plurality of small pieces 3a, 3b, 4a, and 4b are stored are put in the resublimation chamber 11. The resublimation chamber 11 can be evacuated to a degree of vacuum of approximately 10⁻⁵ Pa. Further, the resublimation chamber 11 is configured such that a temperature of an interior wall can be controlled to a temperature at which the material is not adhered to the interior wall.

The stocker 7 includes a heater 14, so that the stocker 7 and the plurality of small pieces 3a, 3b, 4a, and 4b are heated by the heater 14 in a state in which the resublimation chamber 11 is evacuated.

Moreover, the storage chamber 12 whose temperature is controllable is connected to (i) the resublimation chamber 11 via the piping 15 and (ii) the vapor deposition source 13.

Each of the pipings 15 and 16 can be opened and closed, and a temperature of each of the pipings 15 and 16 is controllable. Further, a temperature of the storage chamber 12 is controlled to a temperature at which a vapor deposition material resublimated from the plurality of small pieces 3a, 3b, 4a, and 4b is re-adhered to a surface of the storage chamber 12.

The stocker 7 and the plurality of small pieces 3a, 3b, 4a, and 4b were heated by the heater 14 so that a temperature of each of the stocker 7 and the plurality of small pieces 3a, 3b, 4a, and 4b reached a temperature at which a material of the hole injection layer/hole transfer layer adhered to the plurality of small pieces 3a, 3b, 4a, and 4b was sublimated. Then, the vapor deposition material thus sublimated was resublimated in the resublimation chamber 11.

Meanwhile, the interior wall of the resublimation chamber 11 was maintained at a temperature at which the vapor deposition material was not adherable to the interior wall. For this reason, the vapor deposition material was not adhered to the interior wall.

Then, the piping 15 provided between the resublimation chamber 11 and the storage chamber 12 was opened, so as to lead the vapor deposition material thus resublimated to the storage chamber 12. In order to efficiently lead the vapor deposition material thus sublimated from the resublimation chamber 11 to the storage chamber 12, a carrier gas was used by a gas flow as illustrated in FIG. 6.

An inert gas was used as the carrier gas so as to avoid reaction of the carrier gas with the vapor deposition material thus sublimated. Examples of such an inert gas encompass an Ar gas. Further, the carrier gas can be circulated, so that a vapor deposition material which cannot be captured in the storage chamber 12 and flows away with the carrier gas can be taken again in the storage chamber 12.

In a case where no carrier gas is available, the gas flow does not need to be used, provided that the vapor deposition material thus sublimated can be sufficiently led from the resublimation chamber 11 to the storage chamber 12. In Embodiment 1, the Ar gas was emitted at a flow rate of 30 sccm.

The interior wall of the storage chamber 12 was controlled to a temperature at which the vapor deposition material is adherable to the interior wall. For this reason, the vapor deposition material was re-adhered in the storage chamber 12. In this way, the vapor deposition material was entirely transferred from the plurality of small pieces 3a, 3b, 4a, and 4b to the storage chamber 12.

Then, the piping 15 provided between the resublimation chamber 11 and the storage chamber 12 was closed. Further, the heater 14 of the stocker 7 was turned off, so that the heating of the stocker 7 and the plurality of small pieces 3a, 3b, 4a, and 4b was stopped. Moreover, the control of the temperature in the resublimation chamber 11 was also stopped.

Then, the piping 16 provided between the storage chamber 12 and the vapor deposition source 13 was opened, so that the temperature of the interior wall of the storage chamber 12 became higher than the temperature at which the vapor deposition material was adherable to the interior wall. Simultaneously, a temperature of a vapor deposition material containing section (not illustrated) provided in the vapor deposition source 13 was controlled to a temperature at which the vapor deposition material was adherable to the vapor deposition material containing section. As in a case where the vapor deposition material was transferred from the plurality of small pieces 3a, 3b, 4a, and 4b of the resublimation chamber 11 to the storage chamber 12, this caused the vapor deposition material to be entirely transferred from the storage chamber 12 to the vapor deposition material containing section provided in the vapor deposition source 13.

Finally, the piping 16 provided between the storage chamber 12 and the vapor deposition source 13 was closed, so that the control of the temperature of the storage chamber 12 was stopped.

According to the steps described above, it was possible to collect and reuse the material of the hole injection layer/hole transfer layer, which material was adhered to the shield plate 3 and the shutter 4. The organic EL vapor deposition device including the recovery device 10 configured to carry out a collection and reuse in such steps made it possible to produce the organic EL display device having high material use efficiency.

In Embodiment 1, the method of the present invention is applied to the material of the hole transfer layer/hole injection layer. Note, however, that the present invention is not limited to this and is applicable to another single material layer. Further, the present invention is applicable to a metal material constituting the second electrode 107, for example. In that case, however, the stocker 7, the plurality of small pieces 3a, 3b, 4a, and 4b, the resublimation chamber 11, the pipings 15 and 16, the storage chamber 12, and the like are required to be made of a material which is impervious to a temperature at which such a metal material is sublimated, and a unfavorable device cost is required. Accordingly, it is preferable that the present invention is applied to an organic material whose sublimation temperature is lower than that of the metal material.

Furthermore, the stocker 7 is heated by the heater in Embodiment 1. Note, however, that the present invention is not limited to this, and the stocker 7 and the plurality of small pieces 3a, 3b, 4a, and 4b can be heated by heating the interior wall of the resublimation chamber 11. In that case, a temperature of the resublimation chamber 11 exceeds at least a temperature at which the vapor deposition material thus sublimated is adherable. For this reason, the temperature of the resublimation chamber 11 does not need to be controlled.

According to the configuration above, the shield plate 3 and the shutter 4 are constituted by the plurality of small pieces 3a, 3b, 4a, and 4b whose shape and size are limited. Therefore, the shield plate 3 and the shutter 4 which are in any shape and size can be constituted by the plurality of small pieces 3a, 3b, 4a, and 4b without being limited by a shape and size of the vacuum chamber 5.

In other words, for example, a production cost of the vacuum vapor deposition device 1 employed for a production of an organic EL can be reduced by use of the plurality of small pieces 3a, 3b, 4a, and 4b having high versatility.

In Embodiment 1, the shield plate 3 and the shutter 4 are constituted by the plurality of small pieces 3a, 3b, 4a, and 4b. Note, however, that the present invention is not limited to this and is applicable to another component.

Moreover, according to the configuration above, a size of each of the plurality of small pieces 3a, 3b, 4a, and 4b is limited. This makes it possible to employ a shared stocker 7 and also to employ a resublimation chamber 11 in a shared size, irrespective of the shape and size of the vacuum chamber 5.

Therefore, as compared with a case where a shield plate and a shutter in any shape and size are employed, for example, it is possible to reduce a production cost of the vacuum vapor deposition device 1 and the recovery device 10 employed for a production of an organic EL.

Furthermore, according to the configuration above, no new component in the vacuum chamber 5 is required other than the piping 16 connecting the vapor deposition source 13 and the storage chamber 12. This also makes it possible, for example, to reduce a production cost of the recovery device 10 including the vacuum vapor deposition device 1 used for a production of an organic EL.

The storage chamber 12 was installed in Embodiment 1. However, the storage chamber 12 does not need to be always installed.

Note that, however, the storage chamber 12 thus installed makes it possible to separate an operation timing of the resublimation chamber 11 and that of the vapor deposition source 13.

Further, since it is possible to change a speed of transferring the vapor deposition material from the resublimation chamber 11 to the storage chamber 12 and that of transferring the vapor deposition material from the storage chamber 12 to the vapor deposition source 13, deterioration of the material due to overheating can be prevented.

Moreover, by performing the transfer of the vapor deposition material from the resublimation chamber 11 to the storage chamber 12 in plural times, it is possible to mix the material adhered to each of the plurality of small pieces 3a, 3b, 4a, and 4b in the storage chamber 12, so as to level off variations in a property of the material for each vapor deposition.

Furthermore, impurities sublimated with the vapor deposition material in the resublimation chamber 11 can be captured in the storage chamber 12, so that the impurities will not reach the vapor deposition source 13.

Due to the advantages described above, it is preferable that the storage chamber 12 is provided.

### (Modification 1)

The recovery device described above is an example in which the resublimation chamber 11 in which the stocker 7 storing the plurality of small pieces 3a, 3b, 4a, and 4b is installed is connected directly or via the storage chamber 12 to the vapor deposition source 13 of the vacuum vapor deposition device 1. However, it is also possible that the resublimation chamber 11 is not connected to the vapor deposition source 13 of the vacuum vapor deposition device 1, and the resublimation chamber 11 and the vapor deposition source 13 of the vacuum vapor deposition device 1 are provided independently.

In other words, it is possible to include a recovery device (sublimation refining device) 10a having the resublimation chamber 11 and the storage chamber 12, independent from the vacuum vapor deposition device 1. In that case, it is also possible to obtain the effects of the present invention described in Embodiment 1.

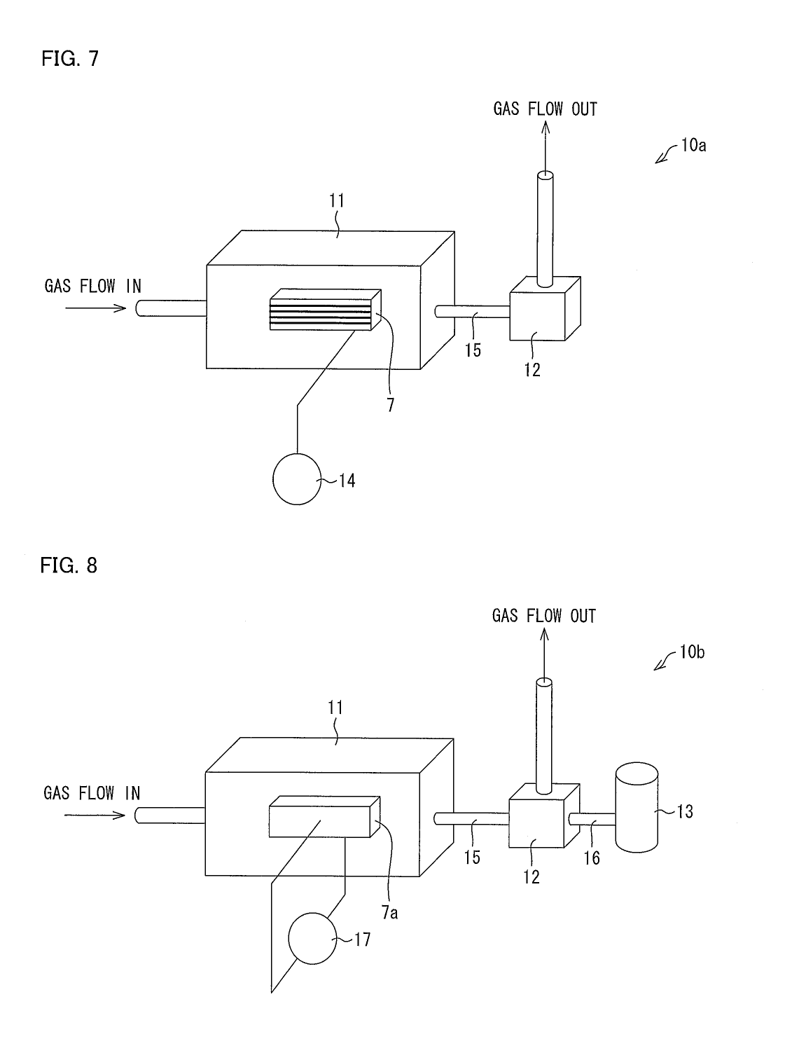

FIG. 7 is a view illustrating a recovery device 10a, which is a modification of the Embodiment 1. The configuration illustrated in FIG. 7 is identical with the configuration illustrated in FIG. 6 as to the resublimation chamber 11 and the storage chamber 12 only. Therefore, for the sake of easy explanation, members having the functions identical with those of the members illustrated in the drawings in Embodiment 1 are labeled with the identical reference signs with those in Embodiment 1 and explanation there is not repeated.

According to a conventional sublimation refining device, since a material in a form of powder packed in a container is heated, an increase of a temperature of the material mostly depends on thermal conductivity of the material itself. Further, the material in the vicinity of a surface of the container may be overheated, so as to be pyrolyzed. In order to avoid that, an additional device such as a stirrer is required.

Meanwhile, according to the recovery device (sublimation refining device) 10a of Modification 1, it is possible to efficiently heat vapor deposition particles thinly adhered to a surface of a plurality of small pieces 3a, 3b, 4a, and 4b by thermal conduction from the plurality of small pieces 3a, 3b, 4a, and 4b. For this reason, the heating can be less dependent on the thermal conductivity of the material itself, and no additional device for preventing overheating such as a stirrer is required. Therefore, a structure of the recovery device (sublimation refining device) 10a can be simplified, so as to allow a reduction of a device cost and miniaturization of the device.

Further, the vapor deposition particles collected by the recovery device (sublimation refining device) 10a illustrated in FIG. 7 are separately supplied to a vapor deposition source 13 under manual operation.

Note that it is possible that a storage chamber 12 includes a vapor deposition material collection container (e.g., crucible or boat) which can be stored in a vapor deposition material containing section 2 provided in a vapor deposition source 13 of a vacuum vapor deposition device 1.

According to such a configuration, it is possible to store a vapor deposition material collection container in which vapor deposition material is collected in the vapor deposition material containing section 2 provided in the vacuum vapor deposition device 1, so as to be used as it is.

### Embodiment 2

Embodiment 2 of the present invention is discussed here with respect to FIG. 8. Embodiment 2 differs from Embodiment 1 in that in Embodiment 2, at least either of a plurality of small pieces (not illustrated) or a stocker 7a is configured to be conductive, so as to be heatable by passing electricity through the at least either of the plurality of small pieces or the stocker 7a. As to other structures, Embodiment 2 is identical with Embodiment 1. Therefore, for the sake of easy explanation, members having the functions identical with those of the members illustrated in the drawings in Embodiment 1 are labeled with the identical reference signs with those in Embodiment 1 and explanation there is not repeated.

FIG. 8 is a view illustrating a schematic structure of the recovery device 10b.

In Embodiment 2, as in Embodiment 1, a shield plate and a shutter were produced by assembling a plurality of small pieces in a vacuum chamber of a film forming vacuum vapor deposition device of a material of the hole injection layer/hole transfer layer.

The plurality of small pieces are identical with those in Embodiment 1 in a shape and a size. However, in Embodiment 2, tantalum (Ta) was used as a material of the plurality of small pieces.

The shield plate and the shutter to which the material was adhered were (i) disassembled into small pieces, (ii) stored in the stocker 7a made of tantalum as same as the plurality of small pieces, and (iii) put in a resublimation chamber 11. The stocker 7a and the plurality of small pieces were connected to a power supply 17 so that electricity can be passed through the stocker 7a and the plurality of small pieces from an outside of the vacuum chamber.

After the resublimation chamber 11 was depressurized to a degree of vacuum of 10⁻⁵ Pa, electricity was passed through the stocker 7a and the plurality of small pieces were simultaneously electrified, so that a temperature of each of the stocker 7a and the plurality of small pieces was increased, by Joule heat, to more than a sublimation temperature of the material adhered to the plurality of small pieces. This sublimated the vapor deposition material to be, thereby separating the vapor deposition material from the plurality of small pieces.

Then, the material was collected in the storage chamber 12 in the same manner as that in Embodiment 1.

According to the steps described above, the vapor deposition material adhered to the shield plate and the shutter can be collected and reused. This makes it possible to produce a vacuum vapor deposition device 1 and a recovery device 10b, each of which has high material use efficiency so as to be applicable as an organic EL production device. As a result, an organic EL display device can be produced at a low cost.

According to the configuration above, since the stocker 7a and the plurality of small pieces are conductive, the stocker 7a and the plurality of small pieces can be directly heated by Joule heat by passing electricity through the stocker 7a and the plurality of small pieces, so that a temperature of the plurality of small pieces can be efficiently increased. Therefore, it is possible to collect and reuse the vapor deposition material by a smaller amount of energy. As a result, it can contribute to reducing a production cost of the organic EL display device.

In Embodiment 2, the stocker 7a and the plurality of small pieces are conductive. However, the present invention is not limited to this, and it is possible that only the stocker 7a is conductive. In that case, the stocker 7a is heated by Joule heat by passing electricity through the stocker 7a and the plurality of small pieces is heated by heat transmission.

Further, it is also possible that only the plurality of small pieces are conductive. In that case, each of the plurality of small pieces is required to be electrically connected so that electricity can be passed through each of the plurality of small pieces. In consideration of easiness of such an electrical connection and energy efficiency in an increase of a temperature, it is preferable that both the stocker 7a and the plurality of small pieces are conductive.

Furthermore, in Embodiment 2, tantalum (Ta) is employed as a material of the stocker 7a and the plurality of small pieces. Note, however, that the present invention is not limited to this, and it is possible to employ a variety of materials, provided that such materials functions to generate Joule heat by passing electricity through the materials, so as to be able to sublimate a vapor deposition material adhered to the plurality of small pieces.

### Embodiment 3

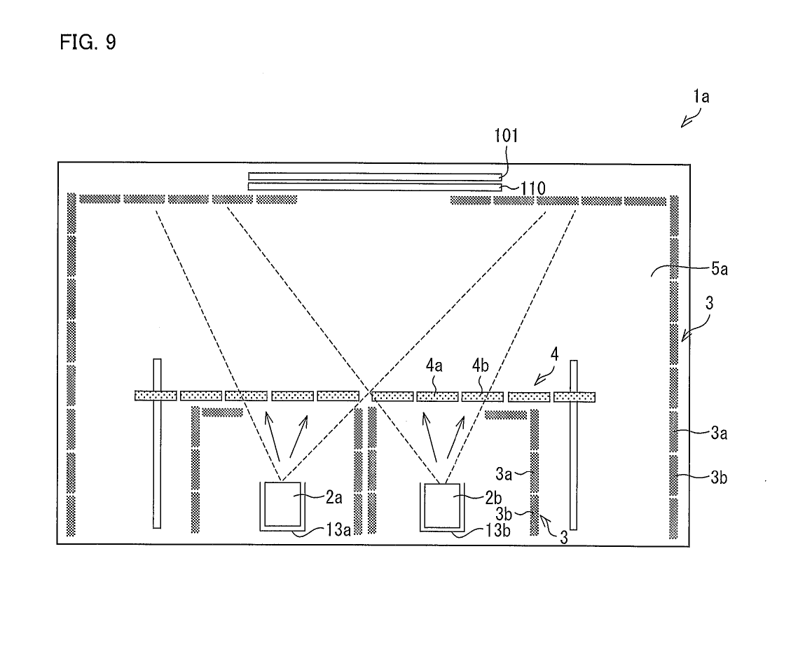

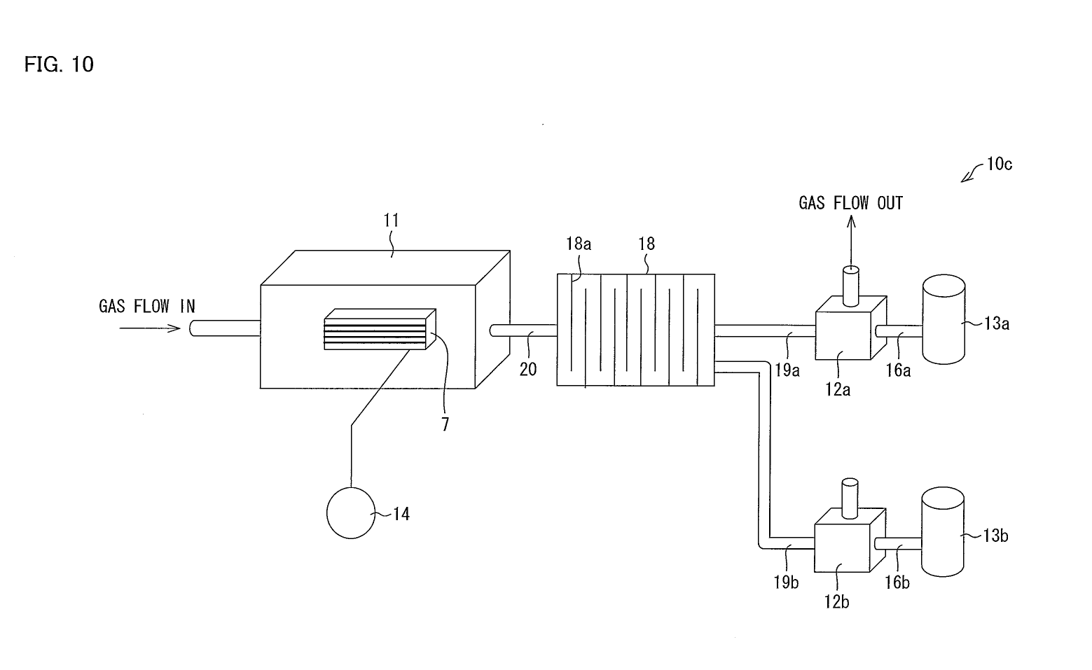

Embodiment 3 of the present invention is discussed here with reference to FIGS. 9 and 10. Embodiment 3 differs from Embodiments 1 and 2 in that in Embodiment 3, a recovery device includes a mechanism which can separate and collect a mixed vapor deposition material. As to other structures, Embodiment 3 is identical with Embodiments 1 and 2. Therefore, for the sake of easy explanation, members having the functions identical with those of the members illustrated in the drawings in Embodiments 1 and 2 are labeled with the identical reference signs with those in Embodiments 1 and 2 and explanation there is not repeated.

FIG. 9 is a view illustrating a schematic structure of a vacuum vapor deposition device 1a.

In a vacuum chamber 5a of the vacuum vapor deposition device 1a for a luminescent layer, (i) a vapor deposition material containing section 2a provided in a vapor deposition source 13a and (ii) a vapor deposition material containing section 2b provided in a vapor deposition source 13b are provided, and a shield plate 3 and a shutter 4 are provided for each of the vapor deposition material containing section 2a and a vapor deposition material containing section 2b. Further, as in Embodiments 1 and 2, a shield plate 3 for the entire vacuum chamber 5a is also provided. The shield plate 3 and the shutter 4 are constituted by assembling the plurality of small pieces 3a, 3b, 4a, and 4b described above.

As illustrated in FIG. 9, a luminescent layer was formed on a substrate 101 by the vacuum vapor deposition device 1a. Specifically, the material was formed on the TFT substrate in the vacuum chamber 5 of the vacuum vapor deposition device 1 illustrated in FIG. 1 for forming a hole injection layer/hole transfer layer.

Then, in a vacuum chamber 5a of the vacuum vapor deposition device 1a for forming the luminescent layer, a luminescent layer consisted by two types of materials, that is, a host material and a guest material, was formed. The host material was sublimated from the vapor deposition material containing section 2a and the guest material was sublimated from the vapor deposition material containing section 2b. In the same time period, the shutters 4 for the vapor deposition material containing sections 2a and 2b were opened, so that a film constituted by a material in which two types of the materials were mixed was formed.

The guest material can efficiently emit light by receiving energy from the host material.

Moreover, an electron transfer layer, an electron injection layer, and a second electrode were formed as a film and sealed in a vacuum chamber of another vacuum vapor deposition device, so that an organic EL display device was produced.

When the organic EL display device was produced according to the process described above, a single vapor deposition material or a mixed vapor deposition material was deposited on a surface of the shield plate 3 and the shutter 4 in the vacuum chamber 5a for the luminescent layer.

FIG. 10 is a view illustrating a schematic structure of a recovery device 10c.

A vacuum chamber 5a was opened. A shield plate 3 and a shutter 4 were delinked into a plurality of small pieces 3a, 3b, 4a, and 4b. Then, the plurality of small pieces 3a, 3b, 4a, and 4b were taken out, stored in a stocker 7, and put in a resublimation chamber 11 illustrated in FIG. 10.

The stocker 7 and the resublimation chamber 11 are identical with those in Embodiment 1. Storage chambers 12a and 12b are provided for a vapor deposition material containing section 2a provided in the vapor deposition source 13a and a vapor deposition material containing section 2b provided in a vapor deposition source 13b, respectively.

Moreover, as illustrated in FIG. 10, a separation chamber 18 in which each of a plurality of interior walls 18a is arranged alternately is provided between the resublimation chamber 11 and a storage chamber 12.

The separation chamber 18 is configured such that a temperature of the interior walls 18a can be controlled to at least a temperature at which a vapor deposition material can be sublimated.

The mixed vapor deposition material was separated and collected in the process described below.

First, a temperature of the plurality of small pieces 3a, 3b, 4a, and 4b in the stocker 7 was increased to a temperature at which both of two types of vapor deposition materials were sublimated. At that time, the interior wall of the resublimation chamber 11 was maintained at a temperature at which none of the two types of vapor deposition materials was adhered to the interior wall.

Simultaneously, a piping 20 connecting the resublimation chamber 11 and the separation chamber 18 was opened, so that the vapor deposition materials thus sublimated was led to the separation chamber 18. The plurality of interior walls 18a in the separation chamber 18 were maintained at a temperature at which (i) one of the two types of vapor deposition materials whose sublimation temperature was higher than that of another type of the two types of vapor deposition materials was adhered to the plurality of interior walls 18a and (ii) the another type of the two types of vapor deposition materials was not adhered to the plurality of interior walls 18a.

In Embodiment 3, the guest material has a higher sublimation temperature than that of the host material. For this reason, not the host material but the guest material is adhered to the plurality of interior walls 18a of the separation chamber 18.

In such a state, a piping 19a connecting the separation chamber 18 and the storage chamber 12a was opened (a piping 19b connecting the separation chamber 18 and the storage chamber 12b was closed).

Since the host material was not adhered to the plurality of interior walls 18a of the separation chamber 18, the host material passed through the separation chamber 18, so as to flow into the storage chamber 12a. Since the storage chamber 12a was set to a temperature at which the host material was adherable thereto, the host material was eventually collected in the storage chamber 12a.

Then, after the host material was entirely collected in the storage chamber 12a, the piping 19a provided between the separation chamber 18 and the storage chamber 12a was closed. In a case where transferring of the guest material from the resublimation chamber 11 to the separation chamber 18 was completed, the piping 20 connecting the resublimation chamber 11 and the separation chamber 18 was also closed.

Then, a temperature of the plurality of interior walls 18a of the separation chamber 18 was increased to a temperature at which the guest material was sublimated. Simultaneously, the piping 19b connecting the separation chamber 18 and the storage chamber 12b was opened. This caused the guest material thus sublimated to flow into the storage chamber 12b. A temperature of the storage chamber 12b was set to a temperature at which the guest material was adherable thereto, so that the guest material was collected in the storage chamber 12b.

According to the steps described above, it was possible to separately collect the host material and the guest material in the storage chamber 12a and the storage chamber 12b, respectively.

Since the host material and the guest material thus collected were supplied, as in Embodiments 1 and 2, from the storage chambers 12a and 12b to the vapor deposition material containing sections 2a and 2b provided in the vapor deposition sources 13a and 13b of the vacuum vapor deposition device 1a illustrated in FIG. 9, explanation is not repeated here.

According to the configuration above, even in a case where two types of materials are mixed and adhered to the plurality of small pieces 3a, 3b, 4a, and 4b constituting the shield plate 3 and the shutter 4, such two types of materials can be efficiently separated by using a difference of such two types of materials in a sublimation temperature, so as to be collected and reused. Therefore, as compared with a case where only a single material adhered to the plurality of small pieces is collected and reused, it is possible to further improve material use efficiency.

In Embodiment 3, a case where the two types of materials are mixed and adhered to the plurality of small pieces 3a, 3b, 4a, and 4b is discussed. Note, however, that the method of the present invention is not limited to this, and is also applicable in a case where three or more types of materials are mixed and adhered to the plurality of small pieces.

It is possible to, with respect to each of the vapor deposition materials, (i) provide a storage chamber connected to a separation chamber and (ii) control a temperature of the interior wall of the separation chamber, by using a difference among the vapor deposition materials in a sublimation temperature, so as to be a temperature at which only one type of the three or more types of vapor deposition materials is not adherable to the interior wall of the separation chamber, so that the one type of the three or more types of vapor deposition materials is taken out, lead to a given storage chamber, and collected. By repeating the process described above, a case where three of more types of the materials are mixed can be handled.

In Embodiment 3, each of the plurality of interior walls 18a was arranged alternately in the separation chamber 18. However, the present invention is not limited to this, and a variety of structure can be employed for the separation chamber. For example, it is possible to arrange many mesh filters in the separation chamber, so that a material required to be adhered is adhered to such many mesh filters.

Note, however, that in order to minimize the separation chamber as small as possible so as to cause the material to be efficiently separated in the separation chamber, it is preferable to form, in the separation chamber, a component having a large surface area. Further, it is preferable for the separation chamber to fulfill a condition that such a component is arranged at a position at which a straight line joining, in the separation chamber, (i) a piping opening from the resublimation chamber and (ii) a piping opening to the storage chamber always crosses the component, so as to prevent vapor deposition particles to be adhered and separated in the separation chamber from entering the storage chamber without colliding with the component in the separation chamber.

In Embodiment 3, the method illustrated in FIG. 10 in which each of the plurality of interior walls 18a is arranged alternately is effective to simply fulfill the condition described above.

In Embodiment 3, the separation chamber 18 is provided so as to separate the mixed vapor deposition material. However, the present invention is not limited to this, and it is also possible to provide no separation chamber 18 by providing a function of the separation chamber 18 to the resublimation chamber 11 and the stocker 7. In that case, a temperature of either the resublimation chamber 11 or the stocker 7 or temperatures of both the resublimation chamber 11 and the stocker 7 is controlled so that only one type of vapor deposition material is sublimated, whereby the material thus sublimated can be collected in a given storage chamber.

Note, however, that in consideration that it is unfavorable, in terms of a device cost and convenience, for the resublimation chamber 11 and the stocker 7 to provide a complex structure in the separation chamber 18, it is preferable to separately provide the separation chamber 18.

In a case where materials having sublimation temperatures very close to each other are mixed, it is difficult to control (i) one of the materials to be adhered to the plurality of interior walls 18a of the separation chamber 18 and (ii) another one of the materials not to be adhered to the plurality of interior walls 18a of the separation chamber 18. Accordingly, it is highly possible that such materials cannot be separated and collected according to the above-mentioned configuration.

In that case, however, it is easily deduced that in a case where the materials thus mixed are heated in one vapor deposition source, such materials are released in a ratio close to a mixing ratio in which the materials were mixed. Therefore, such materials do not always need to be separated and can be also collected and reused as a mixture in (i) a special vapor deposition source for sublimating a mixed material or (ii) a storage chamber connected to the special vapor deposition source. Further, the configurations in Embodiments 1 and 2 are also applicable.

Moreover, it is predicted that a mixing ratio of the mixed material adhered to the shield plate 3 and the shutter 4 differs depending on installed positions or function of the components with which the shield plate 3 and the shutter 4 are assembled. Accordingly, in a case where a plurality of small pieces constituting the components are placed in mix in the stocker 7 and then subjected to the sublimation in the resublimation chamber 11, a mixing ratio of the material collected may differ from that of the material obtained at the time of the vapor deposition of the substrate.

Therefore, a desired mixing ratio may not be obtained even in a case where a material in which a plurality of materials are mixed is released from one vapor deposition source for mixed materials, and a film is formed on a substrate from the materials thus released.

To solve such a case, it is possible to (i) provide another vapor deposition source releasing a single material, (ii) control a releasing amount from the another vapor deposition source in accordance with a release from the vapor deposition source for mixed materials, and (iii) carry out a vapor code position with the materials released from both the vapor deposition source and the another vapor deposition source, so that a vapor-deposited film having a desired mixing ratio can be formed on the substrate.

As described above, the configuration according to Embodiment 3 makes it possible to collect and reuse the mixed vapor deposition material by employing any of the methods described above.

### Embodiment 4

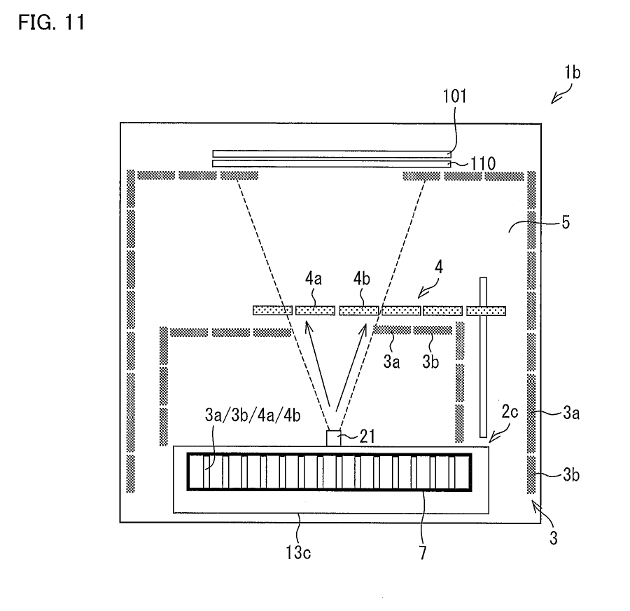

Embodiment 4 of the present invention is discussed here with reference to FIG. 11. Embodiment 4 differs from Embodiments 1 through 3 in that in Embodiment 4, not a resublimation chamber connected from outside but, instead, a vapor deposition source 13c in which a stocker 7 can be stored is provided. As to other structures, Embodiment 4 is the identical with Embodiments 1 through described above. Therefore, for the sake of easy explanation, members having the functions identical with those of the members illustrated in the drawings in Embodiments 1 through 3 are labeled with the identical reference signs with those in Embodiments 1 through 3 and explanation there is not repeated.

FIG. 11 is a view illustrating a schematic structure of a vacuum vapor deposition device 1b.

As illustrated in FIG. 11, the vacuum vapor deposition device 1b includes the vapor deposition source 13c which can store the stocker 7.

A vapor deposition material containing section 2c includes a nozzle opening 21 from which a vapor deposition material is released towards a film-formed substrate 101.

In the same manner as described above, a shield plate 3 and a shutter 4 to each of which the vapor deposition material is adhered are disassembled into a plurality of small pieces 3a, 3b, 4a, and 4b and are stored in the stocker 7.

Then, the stocker 7 is installed in the vapor deposition source 13c.

In a case where the vapor deposition material containing section 2c is heated by a heater (not illustrated), the stocker 7 and the plurality of small pieces 3a, 3b, 4a, and 4b are heated, so that a vapor deposition material sublimated in the vapor deposition material containing section 2c passes through the nozzle opening 21, so as to be released in the vacuum chamber 5.

In a general vapor deposition source, since a material in a form of powder packed in a container is heated, an increase of a temperature of the material mostly depends on thermal conductivity of the material itself. Further, the material in the vicinity of a surface of the container may be overheated, so as to be pyrolyzed. In order to avoid that, it is conventionally impossible to increase a heating temperature.

Accordingly, even though a vapor deposition speed increases as the heating temperature increases, the heating temperature cannot be increased due to the reasons described above. Therefore, it is conventionally difficult to obtain a high vapor deposition speed.

Meanwhile, according to the configuration described in Embodiment 4, it is possible to efficiently heat a material thinly adhered to a surface of the plurality of small pieces 3a, 3b, 4a, and 4b by thermal conduction from the plurality of small pieces 3a, 3b, 4a, and 4b. For this reason, the heating can be less dependent on the thermal conductivity of the material itself, and the heating temperature can be also increased.

Accordingly, the vapor deposition speed can be further increased. Simultaneously, pyrolysis of the vapor deposition material can be further restrained.

Moreover, in Embodiment 4, no additional resublimation chamber or storage chamber as described in Embodiments 1 through 3 is required. Accordingly, the configuration of the device can be more simplified.

In Embodiment 4, the vapor deposition material containing section 2c including one nozzle opening 21 was employed. However, the present invention is not limited to this, and it is also possible to employ a vapor deposition material containing section having a large number of nozzle openings or a slit opening.

Note, however, that in these structures, it should be prevented that releasing amounts of a vapor deposition material from different nozzle openings or from different positions in the slit opening are different due to quantitative variations in the vapor deposition material sublimated from the plurality of small pieces.

For example, this can be done by arranging a mesh component between the nozzle openings or the slit opening and the plurality of small pieces, so as to equalize the amount of the material sublimated in the vapor deposition material containing section and released via each of the nozzle openings or the slit opening.

According to the configuration described in Embodiment 4, it is possible to carry out not separately but simultaneously a collection and reuse of the vapor deposition material.

### Embodiment 5

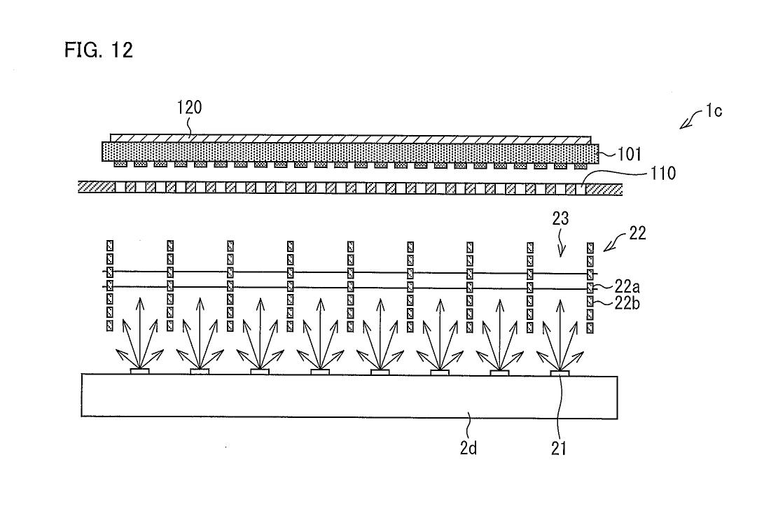

Embodiment 5 of the present invention is discussed here with reference to FIG. 12. Embodiment 5 describes an example in which control plates 22 provided in a vacuum vapor deposition device 1c are constituted by a plurality of small pieces 22a and 22b. As to other structures, Embodiment 5 is identical with Embodiments 1 through 3. Therefore, for the sake of easy explanation, explanation members having the functions identical with those of the members illustrated in the drawings in Embodiments 1 through 3 are labeled with the identical reference signs with those in Embodiments 1 through 3 and explanation there is not repeated.

FIG. 12 is a view illustrating a schematic structure of the vacuum vapor deposition device 1c in which the control plates 22 are formed by the plurality of small pieces 22a and 22b.

As illustrated in FIG. 12, in the vacuum vapor deposition device 1c, the plurality of control plates 22 provided between a vapor deposition material containing section 2d and a vapor deposition mask 110 selectively captures vapor deposition particles entering a space between control panels 23 in accordance with an incidence angle of the vapor deposition particles. Therefore, it is arranged such that only vapor deposition particles having an incidence angle equal to or smaller than a predetermined incidence angle enter an opening of the vapor deposition mask 110.

This reduces a largest incidence angle of the vapor deposition particles with respect to a substrate 101, so as to be able to restrain a blur generated on the substrate 101 hold by a holder 120.

In Embodiment 5, the control plates 22 were formed by assembling the plurality of small pieces 22a and 22b employed in Embodiment 1.

A shield plate (not illustrated) and a shutter (not illustrated) provided in the vacuum vapor deposition device 1c can be also formed by assembling the plurality of small pieces employed in Embodiment 1, for example.

The vapor deposition material adhered to the plurality of small pieces can be collected by the method described above, so as to produce the vacuum vapor deposition device 1c which can efficiently collect the vapor deposition material at a low cost.

Embodiments 1 through 5 describe in detail, as an example, the production device of the organic EL display device by the vacuum vapor deposition method. However, as is clear from the description, the method of the present invention is applicable to (i) a variety of other production devices for efficiently and simply collecting and reusing a vapor deposition material adhered to a component in a vacuum chamber by the vacuum vapor deposition method and (ii) a product produced by such production devices.

The vapor deposition device of the present invention is preferably arranged such that in a given time period, at least the vapor deposition particles released in the first direction from the vapor deposition material containing section are deposited on a second member provided between the vapor deposition material containing section and the substrate, the second member being removable from the vapor deposition device, at least a part of the second member being constituted by a plurality of small pieces linked to one other.

According to the configuration above, the second member, for example, at least a part of the shutter section is also constituted by the plurality of small pieces linked to one another.

The second member is removable from the vapor deposition device and the plurality of small pieces constituting the second member are easily delinked from one another.

Accordingly, it is possible to produce a vapor deposition device which can further efficiently collect a vapor deposition material at a low cost.

The vapor deposition device of the present invention may be arranged such that the first member is a shield plate for protecting the vapor deposition chamber from being contaminated with the vapor deposition particles.

The vapor deposition device of the present invention may be arranged such that the first member is a plurality of control plates provided between (A) an opening through which the vapor deposition particles are released from the vapor deposition material containing section and (B) the substrate, the plurality of control plates being provided along a direction perpendicular to a normal direction of the substrate so as to be placed with a predetermined gap, within both sides of which gap the opening is extended.

According to the configuration above, at least a part of the shield plate and the control plates on which a relatively large number of the deposition particles are expected to be deposited is constituted by the plurality of small pieces linked to one another.

Further, the plurality of small pieces are easily delinkable from one another.

Accordingly, it is possible to produce a vapor deposition device which can further efficiently collect a vapor deposition material at a low cost.

The vapor deposition device of the present invention is preferably arranged such that the vapor deposition source is configured to be able to store a storage member for storing the plurality of small pieces.

According to the configuration above, the plurality of small pieces on which a large amount of vapor deposition material is deposited can be heated all at once in the storage member, so that the vapor deposition material to be collected and reused can be simply resublimated.

Further, the vapor deposition source provided in the vapor deposition device is configured to be able to store a storage member for storing the plurality of small pieces on which the vapor deposition material is deposited, so that the vapor deposition material can be simultaneously collected and reused.

The recovery device of the present invention is preferably arranged such that the first capturing section is connected to the vapor deposition material containing section provided in the vapor deposition device, and the vapor deposition particles captured by means of the first capturing section is supplied to the vapor deposition material containing section by heating the first capturing section at a temperature not less than a sublimation temperature of the vapor deposition particles thus captured.

According to the configuration above, the sublimation section and the first capturing section are provided, and the first capturing section is connected to the vapor deposition material containing section. For this reason, it is possible to separate a step of sublimating vapor deposition particles in the sublimation section, a step of capturing the vapor deposition particles thus sublimated in the first capturing section, and a step of supplying the vapor deposition particles thus captured in the first capturing section to the vapor deposition material containing section, so as to improve a throughput of the recovery device.

Further, according to the configuration above, the vapor deposition particles thus captured in the first capturing section can be supplied as it is to the vapor deposition material containing section provided in the vapor deposition device, so that it is possible to produce a recovery device which can efficiently collect the vapor deposition material at a low cost.

The recovery device of the present invention may be arranged such that the first capturing section is the vapor deposition source.

According to the configuration above, a time period required for a step of supplying the vapor deposition particles thus captured from the first capturing section to the vapor deposition source can be omitted, so as to further improve a throughput of the recovery device.

The recovery device of the present invention is preferably arranged such that the first capturing section includes a vapor deposition material collecting container which is storable in the vapor deposition material containing section provided in the vapor deposition source of the vapor deposition device, and which is configured to collect the vapor deposition particles captured by means of the first capturing section.

According to the configuration above, the first capturing section is configured to include the vapor deposition material collection container which can be stored in the vapor deposition material containing section, so as to collect, in the vapor deposition material collection container, the vapor deposition particles thus captured.

Accordingly, the vapor deposition material collection container in which the vapor deposition material is collected can be stored in the vapor deposition material containing section provided in the vapor deposition device and employed as it is, so as to improve a throughput of the recovery device.

The recovery device of the present invention is preferably arranged such that the at least either the plurality of small pieces or the storage member is formed of an electrically conductive material, and is configured to be heated by Joule heat caused by passing electricity through the at least either the plurality of small pieces or the storage member, so as to carry out the sublimation of the vapor deposition particles deposited on the plurality of small pieces.

According to the configuration above, the vapor deposition material deposited on the plurality of small pieces can be efficiently heated.

The recovery device of the present invention is preferably arranged such that the plurality of small pieces and the storage member are placed in the sublimation section, and a wall surface of the sublimation section is heated so as to sublimate the vapor deposition particles deposited on the plurality of small pieces.

According to the configuration above, the plurality of small pieces and the storage member are heated in the sublimation section itself, so that no additional heating device is required for the plurality of small pieces and the storage member.

The recovery device of the present invention is preferably arranged such that at least two types of vapor deposition particles different from each other are deposited on the plurality of small pieces, and the wall surface of the sublimation section is heated at a temperature at which only one type of vapor deposition particles deposited on the plurality of small pieces is sublimatable.

The recovery device of the present invention is preferably arranged such that at least two types of vapor deposition particles different from each other are deposited on the plurality of small pieces, and at least either the plurality of small pieces or the storage member is heated at a temperature at which only one type of vapor deposition particles deposited on the plurality of small pieces is sublimatable.

According to the configuration above, only the one type of vapor deposition particles deposited on the plurality of small pieces are sublimated, so that even in a case where at least two types of vapor deposition particles different from each other are mixed and deposited on the plurality of small pieces, such at least two types of vapor deposition particles can be separated and collected.

The recovery device of the present invention is preferably arranged such that at least two types of vapor deposition particles different from each other are deposited on the plurality of small pieces, a separation section is provided between the sublimation section and the first capturing section, the separation section has a plurality of interior walls (i) whose temperature is controllable and (ii) which are in contact with the at least two types of vapor deposition particles which are different from each other and are sublimated in the sublimation section, the temperature of the plurality of interior walls is set to not less than a lowest temperature but less than a second lowest temperature among sublimation temperatures of the at least two types of vapor deposition particles which are different from each other and are sublimated, and the at least two types of vapor deposition particles which are different from each other and are sublimated in the sublimation section are supplied to the first capturing section via the separation section.

According to the configuration above, the use of the separation section makes it possible to separate and collect such vapor deposition particles even in a state in which a plurality of types of vapor deposition particles are sublimated in the sublimation chamber.

The recovery device of the present invention is preferably arranged such that in a case where only one type of vapor deposition particles is deposited on the plurality of interior walls of the separation section, the sublimation of the vapor deposition particles deposited on the plurality of interior walls of the separation section is carried out with a temperature of the plurality of interior walls set to not less than the second lowest temperature, so as to supply the vapor deposition particles to a second capturing section different from the first capturing section.

The recovery device of the present invention is preferably arranged such that in a case where two or more types of vapor deposition particles are deposited on the plurality of interior walls of the separation section, the sublimation of the vapor deposition particles is carried out with a temperature of the plurality of interior walls set to not less than a lowest temperature but less than a second lowest temperature in a sublimation temperature of the two or more types of vapor deposition particles deposited on the plurality of interior walls of the separation section, so that only one type of vapor deposition particles is sublimated among the two or more types of vapor deposition particles deposited on the plurality of interior walls of the separation section, so as to supply the vapor deposition particles to a second capturing section different from the first capturing section.

According to the configuration above, the vapor deposition particles deposited on the separation section can be efficiently separated and collected.

The present invention is not limited to the description of the embodiments above, but may be altered by a skilled person within the scope of the claims. An embodiment based on a proper combination of technical means disclosed in different embodiments is encompassed in the technical scope of the present invention.

### INDUSTRIAL APPLICABILITY

The present invention is suitably applicable, for example, to a vapor deposition device and a recovery device for collecting a vapor deposition material.

### REFERENCE SIGNS LIST

1, 1a, 1b, 1c: Vacuum vapor deposition device (Vapor deposition device)
2: Vapor deposition material containing section
3: Shield plate
3a, 3b: Small piece
4: Shutter
4a, 4b: Small piece
5, 5a: Vacuum chamber (Vapor deposition chamber)
7, 7a: Stocker (Storage member)
10, 10a, 10b, 10c: Sublimation refining device (Recovery device)
11: Resublimation chamber (Sublimation section)
12, 12a, 12b: Storage chamber (Capturing section)
13, 13a, 13b, 13c: Vapor deposition source
14: Heater
15: Piping
16, 16a, 16b: Piping
17: Power supply
18: Separation chamber (Separation section)
18a: Interior wall
19a, 19b: Piping
20: Piping
21: Nozzle opening (Opening)
22: Control plate
22a, 22b: Small piece
101: Substrate
110: Shadow mask

1. A vapor deposition device for depositing vapor deposition particles onto a substrate in a vapor deposition chamber, the vapor deposition particles being released from a vapor deposition material containing section provided in a vapor deposition source, wherein:
vapor deposition particles released in a first direction from the vapor deposition material containing section is deposited on the substrate,
vapor deposition particles released in a second direction different from the first direction is deposited on a first member which is removable from the vapor deposition device,
at least a part of the first member is constituted by a plurality of small pieces linked to one another, and
each of the plurality of small pieces is provided with a linking section or linking sections by which each of the plurality of small pieces is linkable to one another and delinkable from one another.

2. The vapor deposition device as set forth in claim 1, wherein:
in a given time period, at least the vapor deposition particles released in the first direction from the vapor deposition material containing section are deposited on a second member provided between the vapor deposition material containing section and the substrate, the second member being removable from the vapor deposition device,
at least a part of the second member being constituted by a plurality of small pieces linked to one other.

3. The vapor deposition device as set forth in claim 1, wherein:
the first member is a shield plate for protecting the vapor deposition chamber from being contaminated with the vapor deposition particles.

4. The vapor deposition device as set forth in claim 1, wherein:
the first member is a plurality of control plates provided between (A) an opening through which the vapor deposition particles are released from the vapor deposition material containing section and (B) the substrate, the plurality of control plates being provided along a direction perpendicular to a normal direction of the substrate so as to be placed with a predetermined gap, within both sides of which gap the opening is extended.

5. The vapor deposition device as set forth in claim 1, wherein:
the vapor deposition source is configured to be able to store a storage member for storing the plurality of small pieces.

6. A recovery device comprising:
a storage member in which the plurality of small pieces having been provided in the vapor deposition device as set forth in claim 1 are stored;
a sublimation section for heating at least either the plurality of small pieces or the storage member so as to sublimate vapor deposition particles deposited on the plurality of small pieces; and
a first capturing section for capturing the vapor deposition particles thus sublimated.

7. A recovery device comprising:
the vapor deposition device as set forth in claim 1;
a storage member for storing therein the plurality of small pieces on which vapor deposition particles are deposited in the vapor deposition chamber provided in the vapor deposition device;
a sublimation section for heating at least either the plurality of small pieces or the storage member so as to sublimate the vapor deposition particles deposited on the plurality of small pieces; and
a first capturing section for capturing the vapor deposition particles thus sublimated.

8. The recovery device as set forth in claim 7, wherein:
the first capturing section is connected to the vapor deposition material containing section provided in the vapor deposition device, and
the vapor deposition particles captured by means of the first capturing section is supplied to the vapor deposition material containing section by heating the first capturing section at a temperature not less than a sublimation temperature of the vapor deposition particles thus captured.

9. The recovery device as set forth in claim 7, wherein the first capturing section is the vapor deposition source.

10. The recovery device as set forth in claim 6, wherein:
the first capturing section includes a vapor deposition material collecting container which is storable in the vapor deposition material containing section provided in the vapor deposition source of the vapor deposition device, and which is configured to collect the vapor deposition particles captured by means of the first capturing section.

11. The recovery device as set forth in claim 6, wherein:
the at least either the plurality of small pieces or the storage member is formed of an electrically conductive material, and is configured to be heated by Joule heat caused by passing electricity through the at least either the plurality of small pieces or the storage member, so as to carry out the sublimation of the vapor deposition particles deposited on the plurality of small pieces.

12. The recovery device as set forth in claim 6, wherein:
the plurality of small pieces and the storage member are placed in the sublimation section, and
a wall surface of the sublimation section is heated so as to sublimate the vapor deposition particles deposited on the plurality of small pieces.

13. The recovery device as set forth in claim 12, wherein:
at least two types of vapor deposition particles different from each other are deposited on the plurality of small pieces, and
the wall surface of the sublimation section is heated at a temperature at which only one type of vapor deposition particles deposited on the plurality of small pieces is sublimatable.

14. The recovery device as set forth in claim 6, wherein:
at least two types of vapor deposition particles different from each other are deposited on the plurality of small pieces, and
at least either the plurality of small pieces or the storage member is heated at a temperature at which only one type of vapor deposition particles deposited on the plurality of small pieces is sublimatable.

15. The recovery device as set forth in claim 6, wherein:
at least two types of vapor deposition particles different from each other are deposited on the plurality of small pieces,
a separation section is provided between the sublimation section and the first capturing section,
the separation section has a plurality of interior walls (i) whose temperature is controllable and (ii) which are in contact with the at least two types of vapor deposition particles which are different from each other and are sublimated in the sublimation section,
the temperature of the plurality of interior walls is set to not less than a lowest temperature but less than a second lowest temperature among sublimation temperatures of the at least two types of vapor deposition particles which are different from each other and are sublimated, and
the at least two types of vapor deposition particles which are different from each other and are sublimated in the sublimation section are supplied to the first capturing section via the separation section.

16. The recovery device as set forth in claim 15, wherein:
in a case where only one type of vapor deposition particles is deposited on the plurality of interior walls of the separation section, the sublimation of the vapor deposition particles deposited on the plurality of interior walls of the separation section is carried out with a temperature of the plurality of interior walls set to not less than the second lowest temperature, so as to supply the vapor deposition particles to a second capturing section different from the first capturing section.

17. The recovery device as set forth in claim 15, wherein:
in a case where two or more types of vapor deposition particles are deposited on the plurality of interior walls of the separation section, the sublimation of the vapor deposition particles is carried out with a temperature of the plurality of interior walls set to not less than a lowest temperature but less than a second lowest temperature in a sublimation temperature of the two or more types of vapor deposition particles deposited on the plurality of interior walls of the separation section, so that only one type of vapor deposition particles is sublimated among the two or more types of vapor deposition particles deposited on the plurality of interior walls of the separation section, so as to supply the vapor deposition particles to a second capturing section different from the first capturing section.
